(19) United States
(12) Patent Application Publication
(10) Pub. No.: US 2025/0040375 A1
(43) Pub. Date: Jan. 30, 2025

(54) DISPLAY DEVICE AND MANUFACTURING METHOD THEREOF

(71) Applicant: Samsung Display Co., Ltd., Yongin-Si (KR)

(72) Inventors: Hwi KIM, Yongin-si (KR); Hye Jin GWARK, Yongin-si (KR); Jae Ik KIM, Yongin-si (KR); Jung Sun PARK, Yongin-si (KR); Seung Yong SONG, Yongin-si (KR); Duck Jung LEE, Yongin-si (KR); Yeon Hwa LEE, Yongin-si (KR); Joon Gu LEE, Yongin-si (KR)

(21) Appl. No.: 18/779,082

(22) Filed: Jul. 22, 2024

(30) Foreign Application Priority Data
Jul. 24, 2023 (KR) 10-2023-0096369

(51) Int. Cl. H10K 59/131; H01L 27/12; H10K 59/12; H10K 59/121; H10K 59/88; H10K 71/60

(52) U.S. Cl. CPC H10K 59/131; H10K 59/1201; H10K 59/1213; H10K 59/88; H10K 71/60; H01L 27/1244

(57) ABSTRACT

A display device may include: a connection pattern and a dummy pattern disposed to be spaced apart from each other on a substrate; a via layer on the substrate; a pixel electrode on the via layer and electrically connected to the connection pattern; a light emitting layer disposed on the pixel electrode; a control layer disposed on the light emitting layer; and a common electrode disposed on the control layer. The dummy pattern may include a first conductive layer, a second conductive layer, a third conductive layer, a fourth conductive layer, and a fifth conductive layer sequentially disposed. The first conductive layer, the third conductive layer, and the fifth conductive layer may include the same material. The second conductive layer and the fourth conductive layer may include the same material. The first, third, fifth conductive layers and the second and fourth conductive layers may include different materials.

### CROSS-REFERENCE TO RELATED APPLICATION

This application claims priority to and the benefit of Korean Patent Application No. 10-2023-0096369 filed in the Korean Intellectual Property Office on Jul. 24, 2023, the entire contents of which are incorporated herein by reference.

### BACKGROUND OF THE INVENTIVE CONCEPT

### (a) Field of the Inventive Concept

Various embodiments of the present disclosure relates to a display device and a manufacturing method thereof.

### (b) Description of the Related Art

Recently, as interest in an information display is increasing, research and development for display devices are continuously conducted.

### SUMMARY OF THE INVENTIVE CONCEPT

The present disclosure may provide a display device with improved reliability and a manufacturing method thereof.

An embodiment of the present disclosure may provide a display device including: a connection pattern and a dummy pattern disposed to be spaced apart from each other on a substrate; a via layer disposed on the substrate and including a contact portion exposing the connection pattern and a via hole exposing the dummy pattern; a pixel electrode disposed on the via layer and electrically connected to the connection pattern through the contact portion; a light emitting layer disposed on the pixel electrode; a control layer disposed on the light emitting layer; and a common electrode disposed on the control layer. The dummy pattern may include a first conductive layer, a second conductive layer, a third conductive layer, a fourth conductive layer, and a fifth conductive layer sequentially disposed on the substrate. The first conductive layer, the third conductive layer, and the fifth conductive layer may include a first conductive material and the second conductive layer and the fourth conductive layer include a second conductive material.

The first conductive material may include titanium. The second conductive layer and the fourth conductive layer may include aluminum.

The second conductive layer and the fourth conductive layer may have a thickness greater than that of the first conductive layer, the third conductive layer, and the fifth conductive layer.

The first conductive layer, the second conductive layer, the third conductive layer, the fourth conductive layer, and the fifth conductive layer may have different thicknesses.

A side surface of the second conductive layer may be disposed inside a side surface of the third layer. A side surface of the fourth layer may be recessed from a side surface of the third conductive layer and a side surface of the fourth conductive layer is recessed from a side surface of the fifth conductive layer.

The side surface of the second conductive layer may be recessed from a side surface of the first conductive layer. The side surface of the fourth conductive layer may be recessed from the side surface of the third conductive layer.

The connection pattern may include a first metal layer, a second metal layer, a third metal layer, a fourth metal layer, and a fifth metal layer sequentially disposed on the substrate. The first metal layer may include the same material as and may be disposed on the same layer as the first conductive layer. The second metal layer may include the same material as and may be disposed on the same layer as the second conductive layer. The third metal layer may include the same material as and may be disposed on the same layer as the third conductive layer. The fourth metal layer may include the same material as and may be disposed on the same layer as the fourth conductive layer. The fifth metal layer may include the same material as and may be disposed on the same layer as the fifth conductive layer.

The control layer may be disconnected on the dummy pattern disposed in the via hole.

The control layer may be disposed on an upper surface of the fifth conductive layer, a portion of a side surface of the fourth conductive layer, a portion of an upper surface of the third conductive layer, a portion of a side surface of the second conductive layer, and an upper surface of the first conductive layer. The common electrode may be disposed on the control layer, side and lower surfaces of the fifth conductive layer, a side surface of the fourth conductive layer, side and lower surfaces of the third conductive layer, and a side surface of the second conductive layer.

The third conductive layer may include an opening exposing a portion of the second conductive layer. The fourth conductive layer may be in direct contact with the second conductive layer exposed via the opening.

The display device may further include a conductive pattern disposed between the dummy pattern and the control layer. The conductive pattern may include the same material as the pixel electrode.

The display device may further include a transistor disposed between the substrate and the connection pattern and electrically connected to the pixel electrode through the connection pattern.

The display device may further include a data line electrically connected to a transistor and receiving a data signal; and a dummy wire disposed to be spaced apart from the data line and integrally formed with the dummy pattern.

The dummy pattern may be electrically connected to the common electrode to receive a low potential voltage.

Another embodiment provides a display device including: a sub-pixel, disposed on a substrate and including a light emitting element including a pixel electrode, a light emitting layer disposed on the pixel electrode, a control layer disposed on the light emitting layer, and a common electrode disposed on the control layer; a connection pattern disposed between the substrate and the light emitting element and electrically connected to the light emitting element; a data line electrically connected to the sub-pixel and receiving a data signal; a dummy wire disposed to be spaced apart from the data line; and a dummy pattern integrally formed with the dummy wire and disposed to be spaced apart from the connection pattern. The dummy pattern may include a first conductive layer, a second conductive layer, a third conductive layer, a fourth conductive layer, and a fifth conductive sequentially disposed on the substrate. The second conductive layer may be in direct contact with the fourth conductive layer.

The first conductive layer, the third conductive layer, and the fifth conductive layer may include titanium, and the second conductive layer and the fourth conductive layer may include aluminum. The second conductive layer and the fourth conductive layer may have a thickness greater than that of the first conductive layer, the third conductive layer, and the fifth conductive layer.

A side surface of the second conductive layer may be recessed from a side surface of the third conductive layer. A side surface of the fourth conductive layer may be recessed from a side surface of the fifth conductive layer.

The third conductive layer may include an opening exposing a portion of the second conductive layer. The second conductive layer and the fourth conductive layer may be connected through the opening.

An embodiment of the present disclosure may provide a manufacturing method of a display device, including: forming a connection pattern and a dummy pattern disposed to be spaced apart from each other on a substrate; forming a via layer disposed on the substrate and including a contact portion exposing the connection pattern and a via hole exposing the dummy pattern; forming a pixel electrode disposed on the via layer and electrically connected to the connection pattern through the contact portion; forming a light emitting layer disposed on the pixel electrode; forming a control layer disposed on the light emitting layer; and forming a common electrode disposed on the control layer. The dummy pattern may include a first conductive layer, a second conductive layer, a third conductive layer, a fourth conductive layer, and a fifth conductive layer sequentially disposed on the substrate. The first conductive layer, the third conductive layer, and the fifth conductive layer may include titanium, and the second conductive layer and the fourth conductive layer may include aluminum. A side surface of the second conductive layer may be recessed from a side surface of the third conductive layer, and a side surface of the fourth conductive layer is recessed from a side surface of the fifth conductive layer.

The forming of the dummy pattern may include sequentially forming a first base conductive layer, a second base conductive layer, and a third base conductive layer on the substrate; forming the first conductive layer, the second conductive layer, and the third conductive layer by collectively etching the first base conductive layer, the second base conductive layer and the third base conductive layer; forming an opening exposing a portion of the second conductive layer by removing a portion of the third conductive layer; and forming the fourth conductive layer on the third conductive layer and forming the fifth conductive layer on the fourth conductive layer.

According to the embodiment, a dummy pattern (or electrode layer) electrically connected to a common electrode (or cathode electrode) may be formed as a five-layered film including a first conductive layer, a second conductive layer, a third conductive layer, a fourth conductive layer, and a fifth conductive layer; the second conductive layer and the fourth conductive layer may be made of aluminum; and a side surface of each of the second conductive layer and the fourth conductive layer may be recessed from a side surface of each of the first conductive layer, the third conductive layer, and the fifth conductive layer. In this case, the second conductive layer may have an undercut portion recessed from a side surface of the third conductive layer, and the fourth conductive layer may have an undercut portion recessed from a side surface of the fifth conductive layer. In case that each of the third conductive layer and the fifth conductive layer has the undercut portion, an area on which a control layer is deposited on the side surface of each of the second conductive layer and the fourth conductive layer of the dummy pattern may be reduced due to the third conductive layer and the fifth conductive layer.

According to the embodiment, a display device with improved reliability and a manufacturing method thereof may be provided by further securing a contact area between the common electrode and the dummy pattern to prevent a voltage drop of the common electrode.

Effects of the embodiment are not limited by what is illustrated in the above, and more various effects are included in the present specification.

### BRIEF DESCRIPTION OF THE DRAWINGS

FIG. 1 illustrates a schematic top plan view of a display device according to an embodiment.

FIG. 2 illustrates a schematic cross-sectional view of a display panel of FIG. 1.

FIG. 3 illustrates a schematic top plan view of an example of a display area of the display panel of FIG. 1.

FIG. 4 illustrates a schematic circuit diagram of an electrical connection relationship of constituent elements included in each of pixels illustrated in FIG. 1.

FIG. 5 and FIG. 6 illustrate schematic top plan views of a pixel according to an embodiment.

FIG. 7 illustrates a schematic top plan view of only constituent elements included in transistors, a first conductive layer, and a second conductive layer in the pixel of FIG. 5.

FIG. 8 illustrates a schematic top plan view of only constituent elements included in a fourth conductive layer in the pixel of FIG. 5.

FIG. 9 illustrates a schematic cross-sectional view taken along line I-I′ of FIG. 6.

FIG. 10, 11 and FIG. 12 illustrate schematic cross-sectional views taken along line II-II′ of FIG. 6.

FIG. 13A and FIG. 13B illustrate schematic plan views of one area of a display area included in the display device of FIG. 1.

FIG. 14, 15, 16, 17, 18, 19, 20, 21, 22 and FIG. 23 illustrate schematic cross-sectional views of a method of forming first and second sub-pixels of FIG. 9 and a dummy pattern of FIG. 10.

FIG. 24, 25, 26 and FIG. 27 illustrate cross-sectional views of a manufacturing method for forming third and seventh connection patterns of FIG. 9 and a dummy pattern of FIG. 11.

### DETAILED DESCRIPTION OF THE EMBODIMENTS

Since the present disclosure may be variously modified and have various forms, embodiments will be illustrated and described in detail in the following. This, however, by no means restricts the inventive concept to the specific embodiments, and it is to be understood as embracing all included in the spirit and scope of the present inventive concept changes, equivalents, and substitutes.

Like reference numerals are used for like constituent elements in describing each drawing. In the accompanying drawings, the dimensions of the structure are exaggerated and shown for clarity of the present disclosure. Terms such as first, second, and the like will be used only to describe various constituent elements, and are not to be interpreted as limiting these constituent elements. The terms are only used to differentiate one constituent element from other constituent elements. For example, a first constituent element could be termed a second constituent element, and similarly, a second constituent element could be termed as a first constituent element, without departing from the scope of the present inventive concept.

In the present application, it should be understood that the term “include”, “comprise”, “have”, or “configure” indicates that a feature, a number, a step, an operation, a constituent element, a part, or a combination thereof described in the specification is present, but does not exclude a possibility of presence or addition of one or more other features, numbers, steps, operations, constituent elements, parts, or combinations, in advance. It will be understood that in case that an element such as a layer, film, region, area, or substrate is referred to as being “on” another element, it can be directly on the other element or intervening elements may also be present. For example, in the present specification, in case that an element of a layer, film, region, area, plate, or the like is referred to as being formed “on” another element, the formed direction is not limited to an upper direction but includes a lateral or lower direction. In contrast, in case an element of a layer, film, region, area, plate, or the like is referred to as being “below” another element, it may be directly below the other element, or intervening elements may be present.

It is to be understood that, in the present application, in case that it is described for one constituent element (for example, a first constituent element) to be (functionally or communicatively) “coupled or connected with/to” another constituent element (for example, a second constituent element), the one constituent element may be directly coupled or connected with/to the another constituent element, or may be coupled or connected with/to through the other constituent element (for example, a third constituent element). In contrast, it is to be understood that in case that it is described for one constituent element (for example, a first constituent element) to be “directly coupled or connected with/to” another constituent element (for example, a second constituent element), there is no other constituent element (for example, a third constituent element) between the one constituent element and the another constituent element.

Hereinafter, with reference to accompanying drawings, a preferred embodiment of the present disclosure and others required for those skilled in the art to understand the contents of the present disclosure will be described in more detail. In the description below, singular forms are to include plural forms unless the context clearly indicates only the singular.

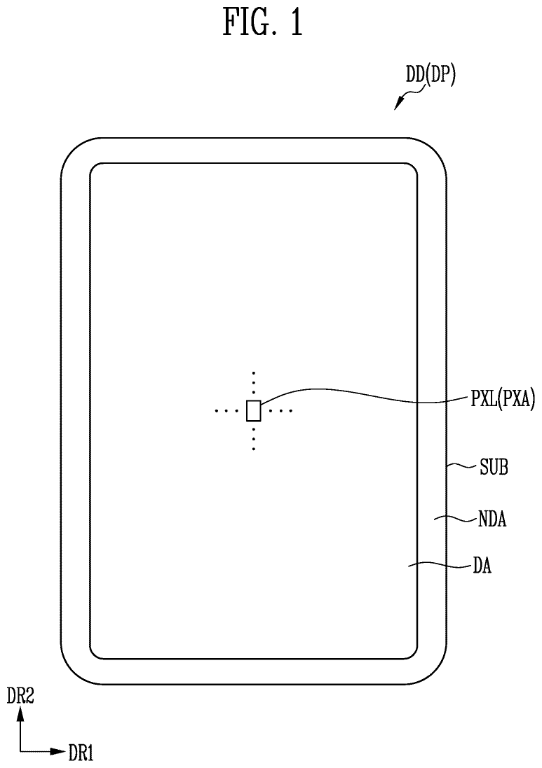

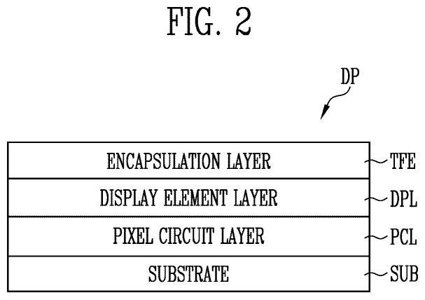

FIG. 1 illustrates a schematic top plan view of a display device DD according to an embodiment, and FIG. 2 illustrates a schematic cross-sectional view of a display panel DP of FIG. 1.

In FIG. 1 and FIG. 2, for the convenience sake, a structure of the display device DD, for example, of a display panel DP provided in the display device DD is briefly illustrated based on a display area DA in which an image is displayed.

Referring to FIG. 1 and FIG. 2, the display panel DP (or the display device DD) according to the embodiment may have various shapes, and for example, the display panel DP may have a rectangular plate shape having two pairs of sides parallel to each other. However, the present inventive concept is not limited thereto. In case that the display panel DP has the rectangular plate shape, sides of one pair of the two pairs of sides may be longer than sides of the other pair thereof.

At least a portion of the display panel DP may have flexibility, and the display panel DP may be folded at the portion having the flexibility, but is not limited thereto.

The display panel DP may display an image. As the display panel DP, a self-light emitting display panel such as an organic light emitting display panel (OLED panel) using an organic light emitting diode as a light emitting element, a micro-LED or nano-LED display panel using an ultra-small light emitting diode as a light emitting element, or a quantum dot organic light emitting display panel (QD OLED panel) using a quantum dot and an organic light emitting diode may be used. For example, as the display panel DP, a non-light emitting display panel such as a liquid crystal display panel (LCD panel), an electro-phoretic display panel (EPD panel), or an electro-wetting display panel (EWD panel) may be used. In case that a non-light emitting display panel is used as the display panel DP, the display device DD may include a backlight unit that supplies light to the display panel DP. In the embodiment, the display panel DP may be an organic light emitting display panel.

The display panel DP may include a substrate SUB and pixels PXL provided on the substrate SUB.

The substrate SUB may include a transparent insulating material and transmit light, but is not limited thereto. The substrate SUB may be a rigid substrate or a flexible substrate.

For example, the rigid substrate may be one of a glass substrate, a quartz substrate, a glass ceramic substrate, and a crystalline glass substrate.

The flexible substrate may be one of a film substrate and a plastic substrate, which include a polymer organic material. For example, the flexible substrate may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate.

One area of the substrate SUB is provided as the display area DA in which pixels PXL are disposed, and the remaining area of the substrate SUB may be provided as a non-display area NDA. For example, the substrate SUB may include the display area DA including pixel areas PXA in which respective pixels PXL are disposed, and the non-display area NDA disposed around the display area DA (or adjacent to the display area DA).

The non-display area NDA may be disposed adjacent to the display area DA. The non-display area NDA may be disposed in at least one side of the display area DA. For example, the non-display area NDA may surround a circumference (or edge) of the display area DA. The non-display area NDA may include a wire portion connected to each pixel PXL and a driver connected to the wire portion and driving the pixel PXL.

Each of the pixels PXL may be provided in the display area DA of the substrate SUB. The pixels PXL may include a light emitting element emitting white light and/or color light and a pixel circuit for driving the light emitting element. The pixel circuit may include at least one transistor electrically connected to the light emitting element. Each pixel PXL may emit light of one of red, green and blue colors, but is not limited thereto. Each pixel PXL may emit light of one of cyan, magenta, yellow and white colors.

A plurality of pixels PXL may be arranged in a matrix format along a pixel row extending in a first direction DR1 and a pixel column extending in a second direction DR2 crossing the first direction DR1. The arrangement of the pixels PXL is not particularly limited, and the pixels PXL may be arranged in various forms. In some embodiments, a plurality of pixels PXL may have different areas (or sizes). For example, in the case in which the pixels PXL have different colors of emitted light, the pixels PXL may have different areas (or sizes) or different shapes.

The driver may provide a predetermined signal and a predetermined voltage to each pixel PXL through the wire portion, thereby controlling driving of the pixel PXL.

The display panel DP (or each of the pixels PXL) may include a pixel circuit layer PCL, a display element layer DPL, and an encapsulation layer TFE disposed on the substrate SUB.

The pixel circuit layer PCL is provided on the substrate SUB, and may include transistors and signal wires connected to the transistors. For example, the transistor may have a structure in which an active pattern (or a semiconductor pattern), a gate electrode, a source electrode and a drain electrode are sequentially stacked with an insulating layer interposed therebetween. The semiconductor pattern may include an amorphous silicon, a poly silicon, a low temperature poly silicon, an organic semiconductor, and/or an oxide semiconductor. The gate electrode, the source electrode, and the drain electrode may include one of aluminum (Al), copper (Cu), titanium (Ti), and molybdenum (Mo), but is not limited thereto. For example, the pixel circuit layer PCL may include at least one or more insulating layers.

The display element layer DPL may be disposed on the pixel circuit layer PCL. The display element layer DPL may include a light emitting element that emits light. The light emitting element may be, for example, an organic light emitting diode, but is not limited thereto. In some embodiments, the light emitting element may be an inorganic light emitting element including an inorganic light emitting material or a light emitting element that emits light by changing a wavelength of light emitted by using a quantum dot.

The encapsulation layer TFE may be disposed on the display element layer DPL. The encapsulation layer TFE may be an encapsulation substrate or a multi-layered encapsulation film. In case that the encapsulation layer TFE is in a form of the encapsulation film, it may include an inorganic film and/or an organic film. For example, the encapsulation layer TFE may have a structure in which an inorganic film, an organic film, and an inorganic film are sequentially stacked. The encapsulation layer TFE may prevent external air and moisture from penetrating into the display element layer DPL and the pixel circuit layer PCL.

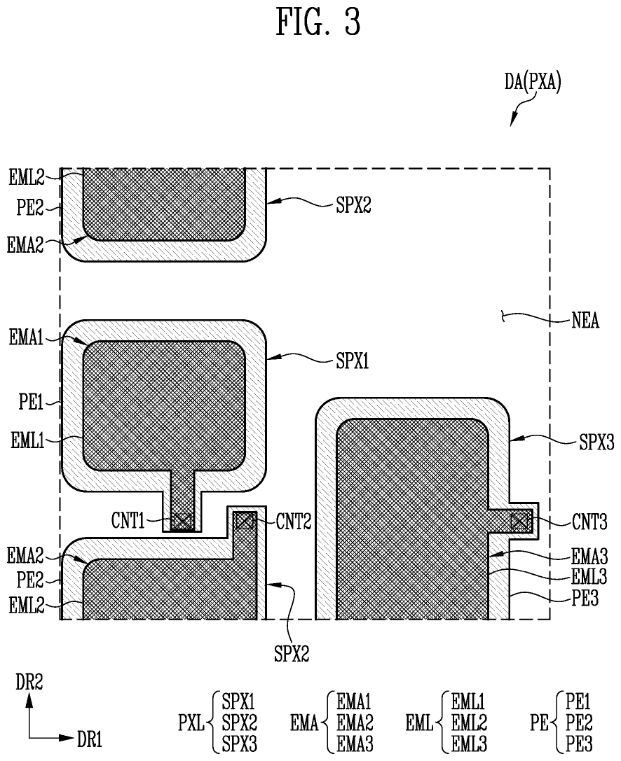

FIG. 3 illustrates a schematic top plan view of an example of the display area DA of the display panel of FIG. 1.

Referring to FIG. 1 to FIG. 3, the pixel PXL may be disposed in the display area DA. The pixel PXL may be disposed in a pixel area PXA provided in the display area DA. The pixel area PXA may include an emission area EMA and a non-emission area NEA.

The pixel PXL may include the first sub-pixel SPX1, the second sub-pixel SPX2, and the third sub-pixel SPX3. The first sub-pixel SPX1 may emit light of a first color, the second sub-pixel SPX2 may emit light of a second color, and the third sub-pixel SPX3 may emit light of a third color. For example, the light of the first color may be light of a red wavelength band, the light of the second color may be light of a green wavelength band, and the light of the third color may be light of a blue wavelength band. However, the present disclosure is not limited thereto.

The first sub-pixel SPX1 may include a first emission area EMA1 and a non-emission area NEA disposed adjacent to the first emission area EMA1 (or surrounding at least one side of the first emission area EMA1). The second sub-pixel SPX2 may include a second emission area EMA2 and a non-emission area NEA disposed adjacent to the second emission area EMA2 (or surrounding at least one side of the second emission area EMA2). The third sub-pixel SPX3 may include a third emission area EMA3 and a non-emission area NEA disposed adjacent to the third emission area EMA3 (or surrounding at least one side of the third emission area EMA3). The first emission area EMA1, the second emission area EMA2, and the third emission area EMA3 may form the emission area EMA of the pixel PXL.

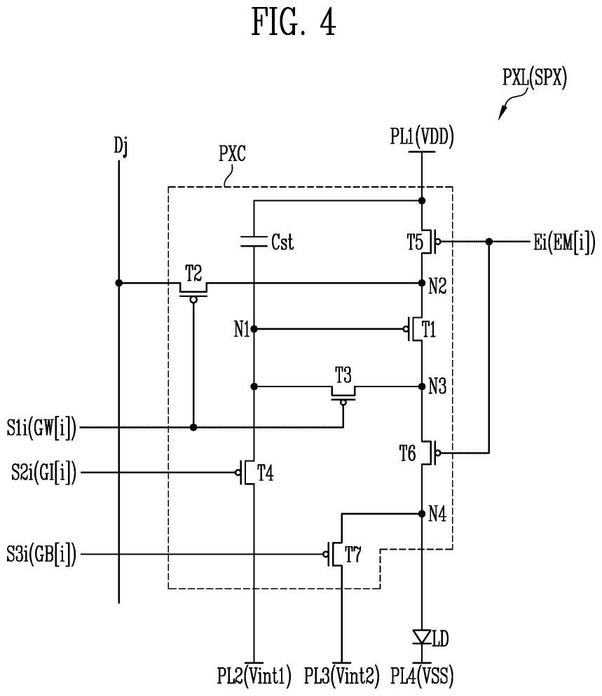

Each of the first, second, and third sub-pixels SPX1, SPX2, and SPX3 may include a light emitting element emitting light (see “LD” in FIG. 4) and circuit elements for driving the light emitting element LD. The first emission area EMA1 may be an area in which light is emitted from the light emitting element LD driven by the circuit elements of the first sub-pixel SPX1. The second emission area EMA2 may be an area in which light is emitted from the light emitting element LD driven by the circuit elements of the second sub-pixel SPX2. The third emission area EMA3 may be an area in which light is emitted from the light emitting element LD driven by the circuit elements of the third sub-pixel SPX3.

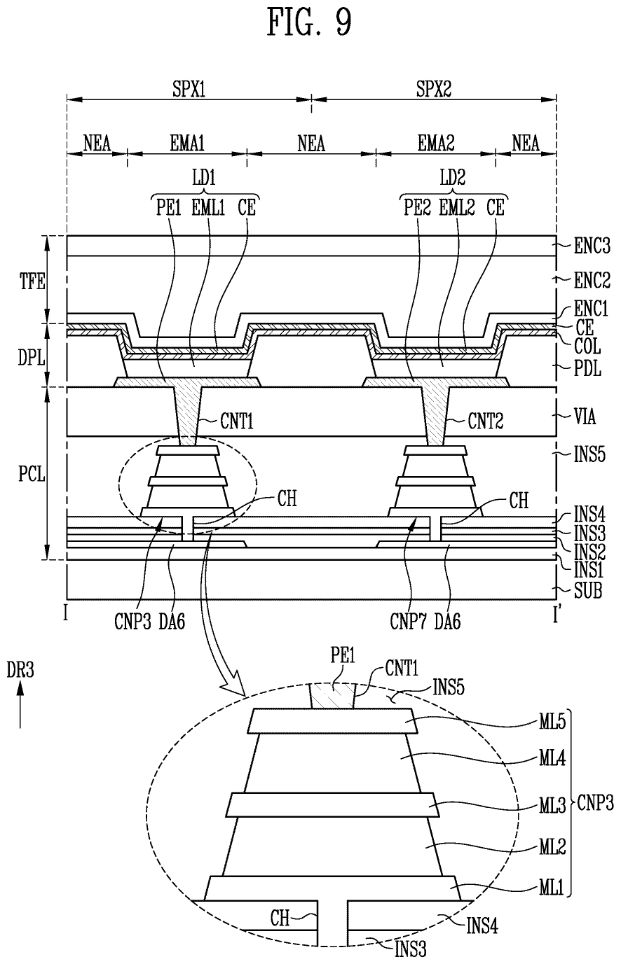

The light emitting element LD disposed in the first sub-pixel SPX1 may include a first pixel electrode PE1, a first light emitting layer EML1 disposed on the first pixel electrode PE1, and a common electrode disposed on the first light emitting layer EML1 (see “CE” in FIG. 9). The light emitting element LD disposed in the second sub-pixel SPX2 may include a second pixel electrode PE2, a second light emitting layer EML2 disposed on the second pixel electrode PE2, and a common electrode CE disposed on the second light emitting layer EML2. The light emitting element LD disposed in the third sub-pixel SPX3 may include a third pixel electrode PE3, a third light emitting layer EML3 disposed on the third pixel electrode PE3, and a common electrode CE disposed on the third light emitting layer EML3. The first pixel electrode PE1, the second pixel electrode PE2, and the third pixel electrode PE3 may configure a pixel electrode PE of the pixel PXL.

In the embodiment, the first pixel electrode PE1 may be electrically connected to a circuit element disposed on the pixel circuit layer PCL of the first sub-pixel SPX1 through a first contact portion CNT1, the second pixel electrode PE2 may be electrically connected to a circuit element disposed on the pixel circuit layer PCL of the second sub-pixel SPX2 through a second contact portion CNT2, and the third pixel electrode PE3 may be electrically connected to a circuit element disposed on the pixel circuit layer PCL of the third sub-pixel SPX3 through a third contact portion CNT3.

FIG. 4 illustrates a schematic circuit diagram of an electrical connection relationship of constituent elements included in each of the pixels PXL illustrated in FIG. 1. For better understanding and ease of description, FIG. 4 illustrates the pixel PXL (or sub-pixel SPX) disposed on an i-th horizontal line (or an i-th pixel row) and connected to a j-th data line Dj.

Referring to FIG. 1 to FIG. 4, the pixel PXL (or sub-pixel SPX) may include a pixel circuit PXC and a light emitting element LD. The pixel circuit PXC may include first, second, third, fourth, fifth, sixth, and seventh transistors T1, T2, T3, T4, T5, T6, and T7, and a storage capacitor Cst.

A first electrode (or pixel electrode) of the light emitting element LD may be connected to a fourth node N4, and a second electrode (or common electrode) thereof may be connected to a fourth power wire PL4. The light emitting element LD may generate light of a predetermined luminance in response to an amount of current (or a driving current) supplied from the first transistor T1. In the embodiment, the light emitting element LD may be an organic light emitting diode including an organic light emitting layer. However, it is not limited thereto, and in some embodiments, the light emitting element LD may be an inorganic light emitting element made of an inorganic material or a light emitting element made of a combination of an inorganic material and an organic material.

The first transistor T1 (or driving transistor) may be electrically connected between a first power wire PL1 and the first electrode of the light emitting element LD. The first transistor T1 may include a gate electrode electrically connected to a first node N1. The first transistor T1 may control the amount of current (or the driving current) flowing from the first power wire PL1 to the fourth power wire PL4 via the light emitting element LD based on a voltage of the first node N1. A first power voltage VDD may be provided from the first power wire PL1, a second power voltage VSS may be provided from the fourth power wire PL4, and the first power voltage VDD may be higher than the second power voltage VSS.

The second transistor T2 may be electrically connected between a j-th data line Dj and a second node N2. A gate electrode of the second transistor T2 may be connected to a (1i)-th scan line S1i (or first scan line). The second transistor T2 may be turned on in case that the first scan signal GW[i] (for example, low-level first scan signal) is supplied to the (1i)-th scan line S1i to electrically connect the j-th data line Dj and the second node N2. In case that the first transistor T1 is turned on, the second transistor T2 may transmit a data signal of the j-th data line Dj to the second node N2 in response to the first scan signal GW[i].

The third transistor T3 may be electrically connected between the first node N1 and a third node N3. A gate electrode of the third transistor T3 may be electrically connected to the (1i)-th scan line S1i. The third transistor T3 may be turned on in case the first scan signal GW[i] is supplied to the (1i)-th scan line S1i. In case that the third transistor T3 is turned on, the first transistor T1 may have a diode-connected structure.

The fourth transistor T4 may be electrically connected between the first node N1 and a second power wire PL2. A gate electrode of the fourth transistor T4 may be electrically connected to a (2i)-th scan line S2i (or second scan line). A first initialization power voltage Vint1 may be provided from the second power wire PL2. The fourth transistor T4 may be turned on by a second scan signal GI[i] supplied from the (2i)-th scan line S2i. In case that the fourth transistor T4 is turned on, the first initialization power voltage Vint1 may be supplied to the first node N1 (that is, the gate electrode of the first transistor T1).

The fifth transistor T5 may be electrically connected between the first power wire PL1 and the second node N2. A gate electrode of the fifth transistor T5 may be electrically connected to an i-th light emitting control line Ei (or light emitting control line). The sixth transistor T6 may be electrically connected between the third node N3 and the light emitting element LD (or the fourth node N4). A gate electrode of the sixth transistor T6 may be electrically connected to the i-th light emitting control line Ei. In case that a light emitting control signal EM[i] (for example, a high level light emission control signal EM[i]) is supplied from the i-th light emitting control line Ei, the fifth transistor T5 and the sixth transistor T6 may be turned off, and in other cases, they may be turned on.

The seventh transistor T7 may be electrically connected between the first electrode (that is, the fourth node N4) of the light emitting element LD and a third power wire PL3. A gate electrode of the seventh transistor T7 may be electrically connected to a (3i)-th scan line S3i . A second initialization power voltage Vint2 may be provided from the third power wire PL3. In some embodiments, the second initialization power voltage Vint2 may be the same as or different from the first initialization power voltage Vint1. The seventh transistor T7 may be turned on by a third scan signal GB[i] supplied from the (3i)-th scan line S3i to supply the second initialization power voltage Vint2 to the first electrode of the light emitting element LD.

The storage capacitor Cst may be connected or formed between the first power wire PL1 and the first node N1.

In some embodiments, the pixel circuit PXC may further include an additional capacitor connected or formed between the first power wire PL1 and the fourth transistor T4 (or the third transistor T3).

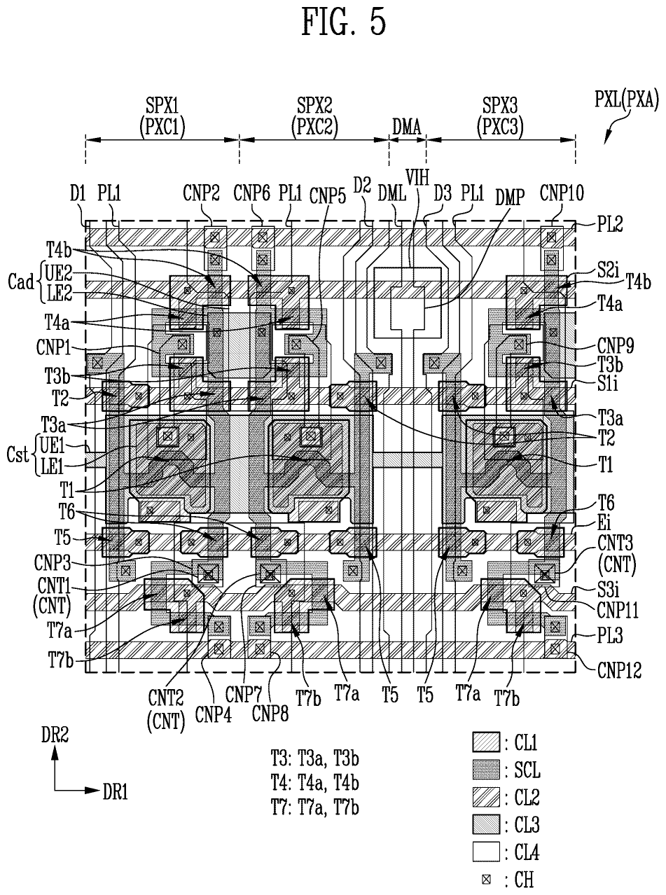

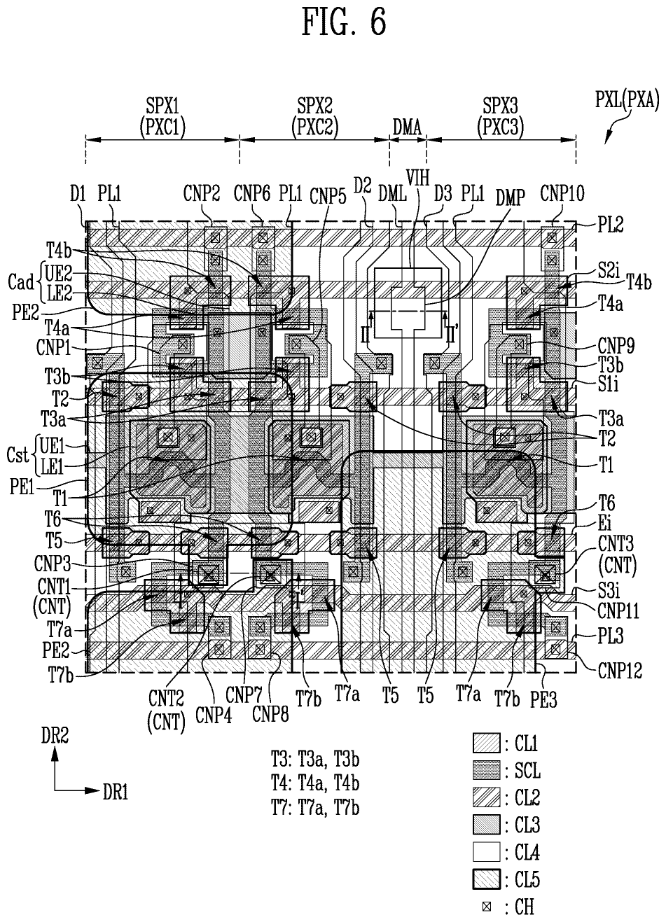

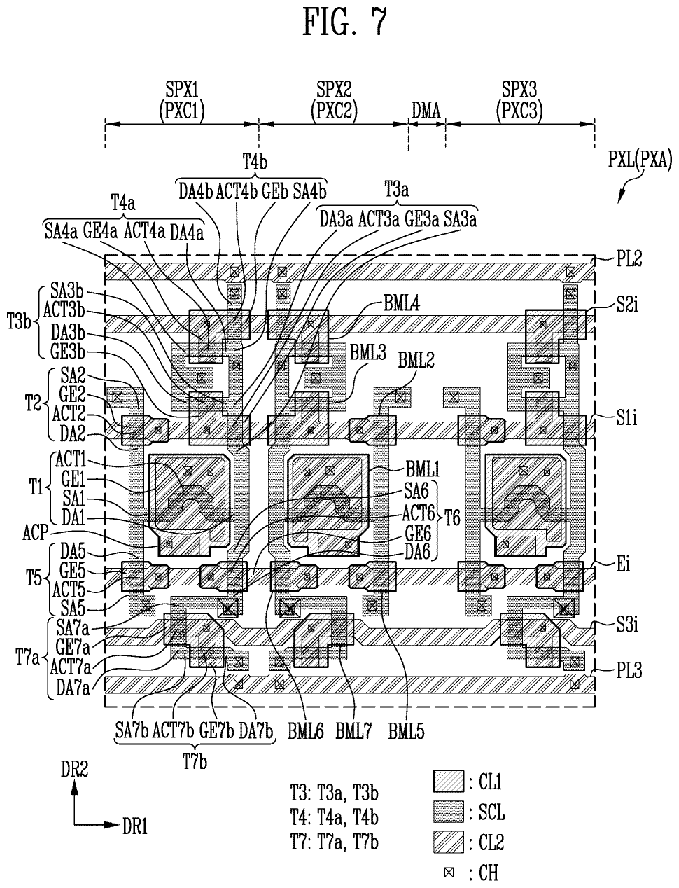

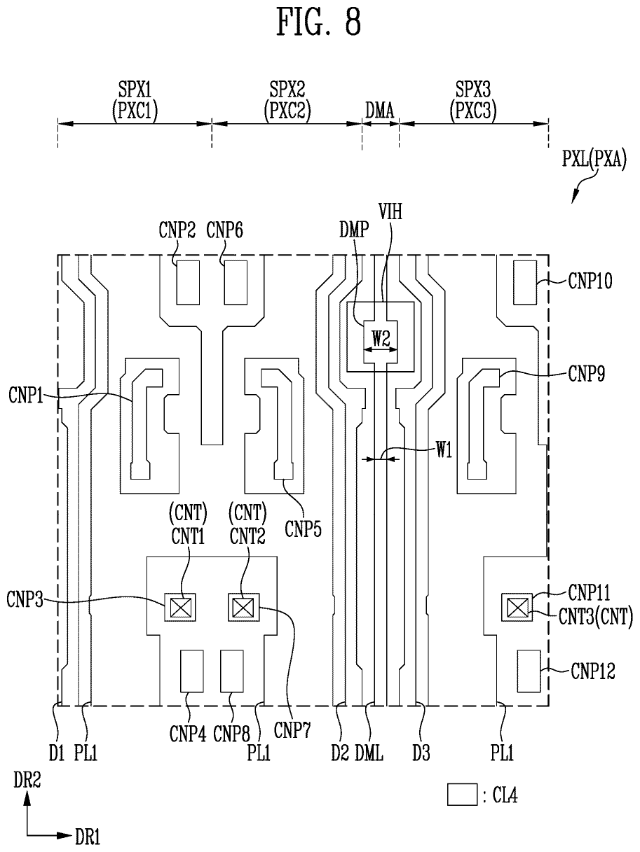

FIG. 5 and FIG. 6 illustrate schematic top plan views of the pixel PXL according to an embodiment, FIG. 7 illustrates a schematic top plan view of only constituent elements included in the transistors T1 to T7, a first conductive layer CL1, and a second conductive layer CL2 in the pixel of FIG. 5, and FIG. 8 illustrates a schematic top plan view of only constituent elements included in a fourth conductive layer CL4 in the pixel of FIG. 5. In FIG. 5 to FIG. 8, for better comprehension and ease of description, the first sub-pixel SPX1 disposed on the i-th horizontal line (or i-th pixel row) and connected to a first data line D1, the second sub-pixel SPX2 disposed on the i-th horizontal line and connected to a second data line D2, and the third sub-pixel SPX3 disposed on the i-th horizontal line and connected to a third data line D3 are illustrated.

In the pixel PXL shown in FIG. 6, the first pixel electrode PE1 of the first sub-pixel SPX1, the second pixel electrode PE2 of the second sub-pixel SPX2, and the third pixel electrode PE3 of the third sub-pixel SPX3 are additionally illustrated in the pixel PXL of FIG. 5.

In FIG. 5 and FIG. 6, for better comprehension and ease of description, the light emitting element electrically connected to the transistors T1 to T7 is omitted.

Referring to FIG. 1 to FIG. 8, the pixel PXL may be disposed in the pixel area PXA. The pixel PXL may include the first sub-pixel SPX1, the second sub-pixel SPX2, and the third sub-pixel SPX3.

The first sub-pixel SPX1 may include a first pixel circuit PXC1 and a light emitting element (refer to “LD” in FIG. 4) driven by the first pixel circuit PXC1. The second sub-pixel SPX2 may include a second pixel circuit PXC2 and the light emitting element LD driven by the second pixel circuit PXC2. The third sub-pixel SPX3 may include a third pixel circuit PXC3 and the light emitting element LD driven by the third pixel circuit PXC3.

Signal wires electrically connected to the first to third sub-pixel SPX1, SPX2, and SPX3 may be disposed in the pixel area PXA. For example, the scan lines S1i, S2i, and S3i, the light emitting control line Ei, the data lines D1, D2, and D3, and the power wires PL1, PL2, and PL3 may be disposed in the pixel area PXA.

The scan lines S1i, S2i, and S3i may extend in a first direction DR1 and include the first scan line S1i, the second scan line S2i, and the third scan line S3i that are spaced apart from each other.

The first, second, and third scan lines (S1i, S2i, and S3i) may be configured of the second conductive layer CL2. The second conductive layer CL2 may be formed as a single layer or a multi-layer made of molybdenum (Mo), copper (Cu), aluminum (Al), chromium (Cr), gold (Au), silver (Ag), titanium (Ti), nickel (Ni), neodymium (Nd), indium (In), tin (Sn), and a oxide thereof or an alloy thereof.

The first scan line S1i may be integrally formed with a second gate electrode GE2 of the second transistor T2 of each of the first, second, and third pixel circuits PXC1, PXC2, and PXC3. In this case, a portion of the first scan line S1i may be the second gate electrode GE2.

For example, the first scan line S1i may be integrally formed with a (3a)-th gate electrode GE3a of a (3a)-th transistor T3a of each of the first, second, and third pixel circuits PXC1, PXC2, and PXC3. In this case, another portion of the first scan line S1i may be the (3a)-th gate electrode GE3a.

Additionally, the first scan line S1i may be integrally formed with a (3b)-th gate electrode GE3b of a (3b)-th transistor T3b of each of the first, second, and third pixel circuits PXC1, PXC2, and PXC3. In this case, another portion of the first scan line S1i may be the (3b)-th gate electrode GE3b.

The second scan line S2i may be integrally formed with a (4a)-th gate electrode GE4a of a (4a)-th transistor T4a of each of the first, second, and third pixel circuits PXC1, PXC2, and PXC3. In this case, a portion of the second scan line S2i may be the (4a)-th gate electrode GE4a.

For example, the second scan line S2i may be integrally formed with a (4b)-th gate electrode GE4b of a (4b)-th transistor T4b of each of the first, second, and third pixel circuits PXC1, PXC2, and PXC3. In this case, another portion of the second scan line S2i may be the (4b)-th gate electrode GE4b.

The third scan line S3i may be integrally formed with a (7a)-th gate electrode GE7a of a (7a)-th transistor T7a of each of the first, second, and third pixel circuits PXC1, PXC2, and PXC3. In this case, a portion of the third scan line S3i may be the (7a)-th gate electrode GE7a.

For example, the third scan line S3i may be integrally formed with a (7b)-th gate electrode GE7b of a (7b)-th transistor T7b of each of the first, second, and third pixel circuits PXC1, PXC2, and PXC3. In this case, another portion of the third scan line S3i may be the (7b)-th gate electrode GE7b.

The light emitting control line Ei may extend in the first direction DR1, and may be disposed to be spaced apart from the first, second, and third scan lines S1i, S2i, and S3i. The light emitting control line Ei may be configured of the second conductive layer CL2.

The light emitting control line Ei may be integrally formed with a fifth gate electrode GE5 of the fifth transistor T5 of each of the first, second, and third pixel circuits PXC1, PXC2, and PXC3. In this case, a portion of the light emitting control line Ei may be the fifth gate electrode GE5.

For example, the light emitting control line Ei may be integrally formed with a sixth gate electrode GE6 of the sixth transistor T6 of each of the first, second, and third pixel circuits PXC1, PXC2, and PXC3. In this case, another portion of the light emitting control line Ei may be the sixth gate electrode GE6.

The data lines D1, D2, and D3 may extend along a second direction DR2, and may include the first data line D1, the second data line D2, and the third data line D3 that are spaced apart from each other. Each of the first to third data lines D1, D2, and D3 may receive a data signal.

The first data line D1 may be electrically connected to the second transistor T2 of the first pixel circuit PXC1, the second data line D2 may be electrically connected to the second transistor T2 of the second pixel circuit PXC2, and the third data line D3 may be electrically connected to the second transistor T2 of the third pixel circuit PXC3. Each of the first to third data lines D1, D2, and D3 may be formed of the fourth conductive layer CL4. The fourth conductive layer CL4 may include the same material as the second conductive layer CL2 described above, or may include one or more materials suitable (or selected) from the materials exemplified as the constituent materials of the second conductive layer CL2, but is not limited thereto. In some embodiments, the fourth conductive layer CL4 may be configured as a five-layered film.

The power wires PL1, PL2, and PL3 may include the first power wire PL1 extending in the second direction DR2, and the second and third power wires PL2 and PL3 extending in the first direction DR1.

The first power wire PL1 may supply the first power voltage VDD. The first power wire PL1 may be disposed to be spaced apart from the data line in each sub-pixel. For example, in the first sub-pixel SPX1, the first power wire PL1 may be disposed to be spaced apart from the first data line D1; in the second sub-pixel SPX2, the first power wire PL1 may be disposed to be spaced apart from the second data line D2; and in the third sub-pixel SPX3, the first power wire PL1 may be disposed to be spaced apart from the third data line D3. In the embodiment, the first power wire PL1 may be configured of the fourth conductive layer CL4, and may be formed in the same process as the first, second, and third data lines D1, D2, and D3 to be disposed on the same layer.

The first power wire PL1 may be electrically connected to an additional conductive pattern ACP through a corresponding contact hole CH. The additional conductive pattern ACP may be configured of the second conductive layer CL2, and may overlap the first power wire PL1. The first power wire PL1 may be electrically connected to an additional conductive pattern ACP disposed on a different layer through a corresponding contact hole CH to form a double layered structure. Accordingly, wire resistance of the first power wire PL1 may be reduced.

The first sub-pixel SPX1 and the second sub-pixel SPX2 may share the first power wire PL1, but are not limited thereto.

In each of the first to third sub-pixels SPX1, SPX2, and SPX3, the first power wire PL1 may be electrically connected to the fifth transistor T5 through a corresponding contact hole CH.

The second power wire PL2 may be supplied with the first initialization power voltage Vint1. The second power wire PL2 may be disposed to be spaced apart from the second scan line S2i in the second direction DR2. The second power wire PL2 may be configured of the second conductive layer CL2. The second power wire PL2 may be a common line commonly provided to the first to third sub-pixels SPX1, SPX2, and SPX3.

In the first sub-pixel SPX1, the second power wire PL2 may be electrically connected to the fourth transistor T4 through a second connection pattern CNP2.

The second connection pattern CNP2 may be configured of the fourth conductive layer CL4. One end of the second connection pattern CNP2 may be electrically connected to the second power wire PL2 through a corresponding contact hole CH. The other end of the second connection pattern CNP2 may be electrically connected to the (4b)-th transistor T4b of the fourth transistor T4 through a corresponding contact hole CH. The second connection pattern CNP2 may electrically connect the second power wire PL2 and the (4b)-th transistor T4b of the first sub-pixel SPX1 (or the first pixel circuit PXC1).

In the second sub-pixel SPX2, the second power wire PL2 may be electrically connected to the fourth transistor T4 through a sixth connection pattern CNP6.

The sixth connection pattern CNP6 may be configured of the fourth conductive layer CL4. One end of the sixth connection pattern CNP6 may be electrically connected to the second power wire PL2 through a corresponding contact hole CH. The other end of the sixth connection pattern CNP6 may be electrically connected to the (4b)-th transistor T4b of the fourth transistor T4 through a corresponding contact hole CH. The sixth connection pattern CNP6 may electrically connect the second power wire PL2 and the (4b)-th transistor T4b of the second sub-pixel SPX2 (or the second pixel circuit PXC2).

In the third sub-pixel SPX3, the second power wire PL2 may be electrically connected to the fourth transistor T4 through a tenth connection pattern CNP10.

The tenth connection pattern CNP10 may be configured of the fourth conductive layer CL4. One end of the tenth connection pattern CNP10 may be electrically connected to the second power wire PL2 through a corresponding contact hole CH. The other end of the tenth connection pattern CNP10 may be electrically connected to the (4b)-th transistor T4b of the fourth transistor T4 through a corresponding contact hole CH. The tenth connection pattern CNP10 may electrically connect the second power wire PL2 and the (4b)-th transistor T4b of the third sub-pixel SPX3 (or the third pixel circuit PXC3).

The third power wire PL2 may be supplied with the second initialization power voltage Vint2. The third power wire PL3 may be disposed to be spaced apart from the third scan line S3i in the second direction DR2. The third power wire PL3 may be configured of the second conductive layer CL2. The third power wire PL3 may be a common line commonly provided to the first to third sub-pixels SPX1, SPX2, and SPX3.

In the first sub-pixel SPX1, the third power wire PL3 may be electrically connected to the seventh transistor T7 through a fourth connection pattern CNP4.

The fourth connection pattern CNP4 may be configured of the fourth conductive layer CL4. One end of the fourth connection pattern CNP4 may be electrically connected to the third power wire PL3 through a corresponding contact hole CH. The other end of the fourth connection pattern CNP4 may be electrically connected to the (7b)-th transistor T7b of the seventh transistor T7 through a corresponding contact hole CH. The fourth connection pattern CNP4 may electrically connect the third power wire PL3 and the (7b)-th transistor T7b of the first sub-pixel SPX1 (or the first pixel circuit PXC1).

In the second sub-pixel SPX2, the third power wire PL3 may be electrically connected to the seventh transistor T7 through a eighth connection pattern CNP8.

The eighth connection pattern CNP8 may be configured of the fourth conductive layer CL4. One end of the eighth connection pattern CNP8 may be electrically connected to the third power wire PL3 through a corresponding contact hole CH. The other end of the eighth connection pattern CNP8 may be electrically connected to the (7b)-th transistor T7b of the seventh transistor T7 through a corresponding contact hole CH. The eighth connection pattern CNP8 may electrically connect the third power wire PL3 and the (7b)-th transistor T7b of the second sub-pixel SPX2 (or the second pixel circuit PXC2).

In the third sub-pixel SPX3, the third power wire PL3 may be electrically connected to the seventh transistor T7 through a twelfth connection pattern CNP12.

The twelfth connection pattern CNP12 may be configured of the fourth conductive layer CL4. One end of the twelfth connection pattern CNP12 may be electrically connected to the third power wire PL3 through a corresponding contact hole CH. The other end of the twelfth connection pattern CNP12 may be electrically connected to the (7b)-th transistor T7b of the seventh transistor T7 through a corresponding contact hole CH. The twelfth connection pattern CNP12 may electrically connect the third power wire PL3 and the (7b)-th transistor T7b of the third sub-pixel SPX3 (or the third pixel circuit PXC3).

The first pixel circuit PXC1, the second pixel circuit PXC2, and the third pixel circuit PXC3 may have substantially similar or identical structures. Hereinafter, the first pixel circuit PXC1 will be mainly described, and the second pixel circuit PXC2 and the third pixel circuit PXC3 will be briefly described.

The first pixel circuit PXC1 may include the first to seventh transistors T1, T2, T3, T4, T5, T6, and T7 and the storage capacitor Cst.

The first transistor T1 may include a first active pattern ACT1, a first gate electrode GE1, a first source area SA1, and a first drain area DA1.

The first active pattern ACT1 may be a partial area of a semiconductor layer SCL overlapped with the first gate electrode GE1. The first active pattern ACT1 configures a channel area of the first transistor T1, and may be a semiconductor pattern not doped with impurities. The first active pattern ACT1 may have a shape bent at least one or more times.

The first source area SA1 is connected to one end of the first active pattern ACT1, and may be a semiconductor pattern doped with impurities. The first source area SA1 may be connected to a second drain area DA2 of the second transistor T2 and a fifth drain area DA5 of the fifth transistor T5.

The first drain area DA1 is connected to the other end of the first active pattern ACT1, and may be a semiconductor pattern doped with impurities. The first drain area DA1 may be connected to a (3a)-th source area SA3a of the (3a)-th transistor T3a and a sixth source area SA6 of the sixth transistor T6.

The first gate electrode GE1 may be disposed on the first active pattern ACT1 to overlap the first active pattern ACT1 in a plan view. The first gate electrode GE1 may have an island-shaped conductive pattern. The first gate electrode GE1 may be configured of the second conductive layer CL2. The first gate electrode GE1 may be electrically connected to the third transistor T3 and the fourth transistor T4 through the first connection pattern CNP1.

The first connection pattern CNP1 may be configured of the fourth conductive layer CL4. One end of the first connection pattern CNP1 may be electrically connected to the first gate electrode GE1 through a corresponding contact hole CH. The other end of the first connection pattern CNP1 may be electrically connected to a portion of the semiconductor layer SCL shared by the (3b)-th transistor T3b and the (4a)-th transistor T4a through a corresponding contact hole CH. For example, a portion of the semiconductor layer SCL may include a (3b)-th drain area DA3b of the (3b)-th transistor T3b and a (4a)-th source area SA4a of the (4a)-th transistor T4a. In the embodiment, the first connection pattern CNP1 may electrically connect the first gate electrode GE1, the (3b)-th drain area DA3b of the (3b)-th transistor T3b, and the (4a)-th source area SA4a of the (4a)-th transistor T4a.

The first gate electrode GE1 may overlap a first lower metal pattern BML1. The first lower metal pattern BML1 may shield the first gate electrode GE1 and the first active pattern ACT1 at the lower side. The first lower metal pattern BML1 may be configured of the first conductive layer CL1. The first conductive layer CL1 may include copper (Cu), molybdenum (Mo), tungsten (W), aluminum neodymium (AlNd), titanium (Ti), aluminum (Al), silver (Ag), and an alloy thereof. The first lower metal pattern BML1 may be provided in an island shape. The first lower metal pattern BML1 may be electrically connected to the first gate electrode GE1 through a corresponding contact hole CH, but is not limited thereto.

The second transistor T2 may include a second active pattern ACT2, a second source area SA2, a second drain area DA2, and a second gate electrode GE2.

The second active pattern ACT2 may be a partial area of the semiconductor layer SCL overlapped with the second gate electrode GE2. The second active pattern ACT2 configures a channel area of the second transistor T2, and may be a semiconductor pattern not doped with impurities.

The second source area SA2 is connected to one end of the second active pattern ACT2, and may be a semiconductor pattern doped with impurities. The second source area SA2 may be electrically connected to the first data line D1 through a corresponding contact hole CH.

The second drain area DA2 is connected to the other end of the second active pattern ACT2, and may be a semiconductor pattern doped with impurities. The second drain area DA2 may be connected to the first source area SA1.

The second gate electrode GE2 may overlap the second active pattern ACT2. The second gate electrode GE2 may be a partial area of the first scan line S1i.

The second gate electrode GE2 may overlap a second lower metal pattern BML2. The second lower metal pattern BML2 may shield the second gate electrode GE2 and the second active pattern ACT2 at the lower side. The second lower metal pattern BML2 may be configured of the first conductive layer CL1. The second lower metal pattern BML2 may be provided in an island shape. The second lower metal pattern BML2 may be electrically connected to the second gate electrode GE2 (or the first scan line S1i) through a corresponding contact hole CH, but is not limited thereto. The second lower metal pattern BML2 may be disposed to be spaced apart from the first lower metal pattern BML1.

The third transistor T3 may have a dual gate structure in which sub-transistors are connected in series to prevent a leakage current. In this case, the third transistor T3 may include the (3a)-th transistor T3a and the (3b)-th transistor T3b.

The (3a)-th transistor T3a may include a (3a)-th active pattern ACT3a, a (3a)-th source area SA3a, a (3a)-th drain area DA3a, and a (3a)-th gate electrode GE3a.

The (3a)-th active pattern ACT3a may be a partial area of the semiconductor layer SCL overlapped with the (3a)-th gate electrode GE3a. The (3a)-th active pattern ACT3a configures a channel area of the (3a)-th transistor T3a, and may be a semiconductor pattern in which impurities are not doped.

The (3a)-th source area SA3a is connected to one end of the (3a)-th active pattern ACT3a, and may be a semiconductor pattern doped with impurities. The (3a)-th source area SA3a may be electrically connected to the first drain area DA1.

The (3a)-th drain area DA3a is connected to the other end of the (3a)-th active pattern ACT3a, and may be a semiconductor pattern doped with impurities. The (3a)-th drain area DA3a may be connected to the (3b)-th source area SA3b of the (3b)-th transistor T3b.

The (3a)-th gate electrode GE3a may overlap the (3a)-th active pattern ACT3a. The (3a)-th gate electrode GE3a may be a partial area of the first scan line S1i.

The (3b)-th transistor T3b may include a (3b)-th active pattern ACT3b, a (3b)-th source area SA3b, a (3b)-th drain area DA3b, and a (3b)-th gate electrode GE3b.

The (3b)-th active pattern ACT3b may be a partial area of the semiconductor layer SCL overlapped with the (3b)-th gate electrode GE3b. The (3b)-th active pattern ACT3b configures a channel area of the (3b)-th transistor T3b, and may be a semiconductor pattern in which impurities are not doped.

The (3b)-th source area SA3b is connected to one end of the (3b)-th active pattern ACT3b, and may be a semiconductor pattern doped with impurities. The (3b)-th source area SA3b may be electrically connected to the (3a)-th drain area DA3a.

The (3b)-th drain area DA3b is connected to the other end of the (3b)-th active pattern ACT3b, and may be a semiconductor pattern doped with impurities. The (3b)-th drain area DA3b may be connected to the (4a)-th source area SA4a of the (4a)-th transistor T4a.

The (3b)-th gate electrode GE3b may overlap the (3b)-th active pattern ACT3b. The (3b)-th gate electrode GE3b may be a partial area of the first scan line S1i.

In the embodiment, the (3a)-th gate electrode GE3a and the (3b)-th gate electrode GE3b may overlap a third lower metal pattern BML3. The third lower metal pattern BML3 may shield the (3a)-th gate electrode GE3a, the (3a)-th active pattern ACT3a, the (3b)-th gate electrode GE3b, and the (3b)-th active pattern ACT3b at the lower side. The third lower metal pattern BML3 may be configured of the first conductive layer CL1. The third lower metal pattern BML3 may be provided in an island shape. The third lower metal pattern BML3 may be electrically connected to the first scan line S1i through a corresponding contact hole CH, but is not limited thereto. The third lower metal pattern BML3 may be disposed to be spaced apart from the first and second lower metal patterns BML1 and BML2.

The fourth transistor T4 may have a dual gate structure in which sub-transistors are connected in series to prevent a leakage current. In this case, the fourth transistor T4 may include the (4a)-th transistor T4a and the (4b)-th transistor T4b.

The (4a)-th transistor T4a may include a (4a)-th active pattern ACT4a, a (4a)-th source area SA4a, a (4a)-th drain area DA4a, and a (4a)-th gate electrode GE4a.

The (4a)-th active pattern ACT4a may be a partial area of the semiconductor layer SCL overlapped with the (4a)-th gate electrode GE4a. The (4a)-th active pattern ACT4a configures a channel area of the (4a)-th transistor T4a, and may be a semiconductor pattern in which impurities are not doped.

The (4a)-th source area SA4a is connected to one end of the (4a)-th active pattern ACT4a, and may be a semiconductor pattern doped with impurities. The (4a)-th source area SA4a may be connected to the (3b)-th drain area DA3b.

The (4a)-th drain area DA4a is connected to the other end of the (4a)-th active pattern ACT4a, and may be a semiconductor pattern doped with impurities. The (4a)-th drain area DA4a may be connected to the (4b)-th source area SA4b of the (4b)-th transistor T4b.

The (4a)-th gate electrode GE4a may overlap the (4a)-th active pattern ACT4a. The (4a)-th gate electrode GE4a may be a partial area of the second scan line S2i.

The (4b)-th transistor T4b may include a (4b)-th active pattern ACT4b, a (4b)-th source area SA4b, a (4b)-th drain area DA4b, and a (4b)-th gate electrode GE4b.

The (4b)-th active pattern ACT4b may be a partial area of the semiconductor layer SCL overlapped with the (4b)-th gate electrode GE4b. The (4b)-th active pattern ACT4b configures a channel area of the (4b)-th transistor T4b, and may be a semiconductor pattern in which impurities are not doped.

The (4b)-th source area SA4b is connected to one end of the (4b)-th active pattern ACT4b, and may be a semiconductor pattern doped with impurities. The (4b)-th source area SA4b may be connected to the (4a)-th drain area DA4a.

The (4b)-th drain area DA4b is connected to the other end of the (4b)-th active pattern ACT4b, and may be a semiconductor pattern doped with impurities. The (4b)-th drain area DA4b may be electrically connected to the second connection pattern CNP2 through a corresponding contact hole CH.

The (4b)-th gate electrode GE4b may overlap the (4b)-th active pattern ACT4b. The (4b)-th gate electrode GE4b may be a partial area of the second scan line S2i.

In the embodiment, the (4a)-th gate electrode GE4a and the (4b)-th gate electrode GE4b may overlap a fourth lower metal pattern BML4. The fourth lower metal pattern BML4 may shield the (4a)-th gate electrode GE4a, the (4a)-th active pattern ACT4a, the (4b)-th gate electrode GE4b, and the (4b)-th active pattern ACT4b at the lower side. The fourth lower metal pattern BML4 may be configured of the first conductive layer CL1. The fourth lower metal pattern BML4 may be provided in an island shape. The fourth lower metal pattern BML4 may be electrically connected to the second scan line S2i through a corresponding contact hole CH, but is not limited thereto. The fourth lower metal pattern BML4 may be disposed to be spaced apart from the first to third lower metal patterns BML1, BML2, and BML3.

The fifth transistor T5 may include a fifth active pattern ACT5, a fifth source area SA5, a fifth drain area DA5, and a fifth gate electrode GE5.

The fifth active pattern ACT5 may be a partial area of the semiconductor layer SCL overlapped with the fifth gate electrode GE5. The fifth active pattern ACT5 configures a channel area of the fifth transistor T5, and may be a semiconductor pattern not doped with impurities.

The fifth source area SA5 is connected to one end of the fifth active pattern ACT5, and may be a semiconductor pattern doped with impurities. The fifth source area SA5 may be electrically connected to the first power wire D1 through a corresponding contact hole CH.

The fifth drain area DA5 is connected to the other end of the fifth active pattern ACT5, and may be a semiconductor pattern doped with impurities. The fifth drain area DA5 may be connected to the first source area SA1.

The fifth gate electrode GE5 may overlap the fifth active pattern ACT5. The fifth gate electrode GE5 may be a partial area of the light emitting control line Ei.

The fifth gate electrode GE5 may overlap a fifth lower metal pattern BML5. The fifth lower metal pattern BML5 may shield the fifth gate electrode GE5 and the fifth active pattern ACT5 at the lower side. The fifth lower metal pattern BML5 may be configured of the first conductive layer CL1. The fifth lower metal pattern BML5 may be provided in an island shape. The fifth lower metal pattern BML5 may be electrically connected to the fifth gate electrode GE5 (or the light emitting control line Ei) through a corresponding contact hole CH, but is not limited thereto. The fifth lower metal pattern BML5 may be disposed to be spaced apart from the first to fourth lower metal patterns BML1, BML2, BML3, and BML4.

The sixth transistor T6 may include a sixth active pattern ACT6, a sixth source area SA6, a sixth drain area DA6, and a sixth gate electrode GE6.

The sixth active pattern ACT6 may be a partial area of the semiconductor layer SCL overlapped with the sixth gate electrode GE6. The sixth active pattern ACT6 configures a channel area of the sixth transistor T6, and may be a semiconductor pattern not doped with impurities.

The sixth source area SA6 is connected to one end of the sixth active pattern ACT6, and may be a semiconductor pattern doped with impurities. The sixth source area SA6 may be connected to the first drain area DA1.

The sixth drain area DA6 is connected to the other end of the sixth active pattern ACT6, and may be a semiconductor pattern doped with impurities. The sixth drain area DA6 may be electrically connected to the third connection pattern CNP3 through a corresponding contact hole CH.

The third connection pattern CNP3 may be configured of the fourth conductive layer CL4. The third connection pattern CNP3 may be electrically connected to the sixth drain area DA6 through a corresponding contact hole CH. The third connection pattern CNP3 may be electrically connected to the first pixel electrode PE1 through the first contact portion CNT1. The third connection pattern CNP3 may electrically connect the first pixel electrode PE1 and the sixth transistor T6.

The sixth gate electrode GE6 may overlap the sixth active pattern ACT6. The sixth gate electrode GE6 may be a partial area of the light emitting control line Ei.

The sixth gate electrode GE6 may overlap a sixth lower metal pattern BML6. The sixth lower metal pattern BML6 may shield the sixth gate electrode GE6 and the sixth active pattern ACT6 at the lower side. The sixth lower metal pattern BML6 may be configured of the first conductive layer CL1. The sixth lower metal pattern BML6 may be provided in an island shape. The sixth lower metal pattern BML6 may be electrically connected to the sixth gate electrode GE6 (or the light emitting control line Ei) through a corresponding contact hole CH, but is not limited thereto. The sixth lower metal pattern BML6 may be disposed to be spaced apart from the first to fifth lower metal patterns BML1, BML2, BML3, BML4, and BML5.

The seventh transistor T7 may have a dual gate structure in which sub-transistors are connected in series to prevent a leakage current. In this case, the seventh transistor T7 may include the (7a)-th transistor T7a and the (7b)-th transistor T7b.

The (7a)-th transistor T7a may include a (7a)-th active pattern ACT7a, a (7a)-th source area SA7a, a (7a)-th drain area DA7a, and a (7a)-th gate electrode GE7a.

The (7a)-th active pattern ACT7a may be a partial area of the semiconductor layer SCL overlapped with the (7a)-th gate electrode GE7a. The (7a)-th active pattern ACT7a configures a channel area of the (7a)-th transistor T7a, and may be a semiconductor pattern in which impurities are not doped.

The (7a)-th source area SA7a is connected to one end of the (7a)-th active pattern ACT7a, and may be a semiconductor pattern doped with impurities. The (7a)-th source area SA7a may be connected to the sixth drain area DA6.

The (7a)-th drain area DA 7a is connected to the other end of the (7a)-th active pattern ACT7a, and may be a semiconductor pattern doped with impurities. The (7a)-th drain area DA7a may be connected to the (7b)-th source area SA7b of the (7b)-th transistor T7b.

The (7a)-th gate electrode GE7a may overlap the (7a)-th active pattern ACT7a. The (7a)-th gate electrode GE7a may be a partial area of the third scan line S3i.

The (7b)-th transistor T7b may include a (7b)-th active pattern ACT7b, a (7b)-th source area SA7b, a (7b)-th drain area DA7b, and a (7b)-th gate electrode GE7b.

The (7b)-th active pattern ACT7b may be a partial area of the semiconductor layer SCL overlapped with the (7b)-th gate electrode GE7b. The (7b)-th active pattern ACT7b configures a channel area of the (7b)-th transistor T7b, and may be a semiconductor pattern in which impurities are not doped.

The (7b)-th source area SA7b is connected to one end of the (7b)-th active pattern ACT7b, and may be a semiconductor pattern doped with impurities. The (7b)-th source area SA7b may be electrically connected to the (7a)-th drain area DA7a.

The (7b)-th drain area DA7b is connected to the other end of the (7b)-th active pattern ACT7b, and may be a semiconductor pattern doped with impurities. The (7b)-th drain area DA7b may be electrically connected to the fourth connection pattern CNP4 through a corresponding contact hole CH.

The (7b)-th gate electrode GE7b may overlap the (7b)-th active pattern ACT7b. The (7b)-th gate electrode GE7b may be a partial area of the third scan line S3i.

In the embodiment, the (7a)-th gate electrode GE7a and the (7b)-th gate electrode GE7b may overlap a seventh lower metal pattern BML7. The seventh lower metal pattern BML7 may shield the (7a)-th gate electrode GE7a, the (7a)-th active pattern ACT7a, the (7b)-th gate electrode GE7b, and the (7b)-th active pattern ACT7b at the lower side. The seventh lower metal pattern BML7 may be configured of the first conductive layer CL1. The seventh lower metal pattern BML7 may be provided in an island shape. The seventh lower metal pattern BML7 may be electrically connected to the third scan line S3i through a corresponding contact hole CH, but is not limited thereto. The seventh lower metal pattern BML7 may be disposed to be spaced apart from the first to sixth lower metal patterns BML1, BML2, BML3, BML4, BML5, and BML6.

The storage capacitor Cst may include a first lower electrode LE1 and a first upper electrode UE1. The first lower electrode LE1 may be integrally formed with the first gate electrode GE1 of the first transistor T1. In this case, the first lower electrode LE1 may be the first gate electrode GE1.

The first upper electrode UE1 may overlap the first lower electrode LE1 in a plan view. Capacitance of the storage capacitor Cst may be increased by increasing an overlapping area of the first upper electrode UE1 and the first lower electrode LE1. The first upper electrode UE1 may extend in the first direction DR1. The first upper electrode UE1 may be configured of the third conductive layer CL3. The third conductive layer CL3 may include the same material as the second conductive layer CL2 described above, or may include one or more materials suitable (or selected) from the materials exemplified as the constituent materials of the second conductive layer CL2, but is not limited thereto. The first upper electrode UE1 may be electrically connected to the first power wire PL1 through a corresponding contact hole CH. The first upper electrode UE1 may have an opening in an area in which a contact hole CH connecting the first gate electrode GE1 and the first connection pattern CNP1 is formed.

The first pixel circuit PXC1 may further include an additional capacitor Cad. The additional capacitor Cad may include a second lower electrode LE2 and a second upper electrode UE2.

The second lower electrode LE2 may be configured of the third conductive layer CL3, and may be provided in an island shape. The second lower electrode LE2 may be connected to the (4a)-th drain area DA4a and the (4b)-th source area SA4b through a corresponding contact hole CH.

The second upper electrode UE2 may overlap the second lower electrode LE2 in a plan view. The second upper electrode UE2 may be integrally formed with the first power wire PL1. In this case, the second upper electrode UE2 may be a partial area of the first power wire PL1.

The second pixel circuit PXC2 may include the first to seventh transistors T1, T2, T3, T4, T5, T6, and T7 and the storage capacitor Cst.

The gate electrode of the first transistor T1 may be electrically connected to the third transistor T3 and the fourth transistor T4 through the fifth connection pattern CNP5.

The fifth connection pattern CNP5 may be configured of the fourth conductive layer CL4. One end of the fifth connection pattern CNP5 may be electrically connected to the gate electrode of the first transistor T1 through a corresponding contact hole CH. The other end of the fifth connection pattern CNP5 may be electrically connected to a portion of the semiconductor layer SCL shared by the (3b)-th transistor T3b and the (4a)-th transistor T4a through a corresponding contact hole CH.

The sixth transistor T6 may be electrically connected to the seventh connection pattern CNP7 through a corresponding contact hole CH.

The seventh connection pattern CNP7 may be configured of the fourth conductive layer CL4. The seventh connection pattern CNP7 may be electrically connected to the drain area of the sixth transistor T6 through a corresponding contact hole CH. The seventh connection pattern CNP7 may be electrically connected to the second pixel electrode PE2 through the second contact portion CNT2. The seventh connection pattern CNP7 may electrically connect the second pixel electrode PE2 and the sixth transistor T6.

The third pixel circuit PXC3 may include the first to seventh transistors T1, T2, T3, T4, T5, T6, and T7 and the storage capacitor Cst.

The gate electrode of the first transistor T1 may be electrically connected to the third transistor T3 and the fourth transistor T4 through the ninth connection pattern CNP9.

The ninth connection pattern CNP9 may be configured of the fourth conductive layer CL4. One end of the ninth connection pattern CNP9 may be electrically connected to the gate electrode of the first transistor T1 through a corresponding contact hole CH. The other end of the ninth connection pattern CNP9 may be electrically connected to a portion of the semiconductor layer SCL shared by the (3b)-th transistor T3b and the (4a)-th transistor T4a through a corresponding contact hole CH.

The sixth transistor T6 may be electrically connected to the eleventh connection pattern CNP11 through a corresponding contact hole CH.

The eleventh connection pattern CNP11 may be configured of the fourth conductive layer CL4. The eleventh connection pattern CNP11 may be electrically connected to the drain area of the sixth transistor T6 through a corresponding contact hole CH. The eleventh connection pattern CNP11 may be electrically connected to the third pixel electrode PE3 through the third contact portion CNT3. The eleventh connection pattern CNP11 may electrically connect the third pixel electrode PE3 and the sixth transistor T6.

Each of the first, second, and third pixel circuits PXC1, PXC2, and PXC3 may be electrically connected to a pixel electrode PE through a corresponding contact portion CNT. For example, the first pixel circuit PXC1 may be electrically connected to the first pixel electrode PE1 through the first contact portion CNT1, the second pixel circuit PXC2 may be electrically connected to the second pixel electrode PE2 through the second contact portion CNT2, and the third pixel circuit PXC3 may be electrically connected to the third pixel electrode PE3 through the third contact portion CNT3.

The first pixel electrode PE1, the second pixel electrode PE2, and the third pixel electrode PE3 may be configured of a fifth conductive layer CL5.

The first pixel electrode PE1 corresponds to the anode electrode of the light emitting element LD disposed in the first sub-pixel SPX1, and may overlap some components of the first pixel circuit PXC1. The second pixel electrode PE2 corresponds to the anode electrode of the light emitting element LD disposed in the second sub-pixel SPX2, and may overlap some components of the second pixel circuit PXC2. The third pixel electrode PE3 corresponds to the anode electrode of the light emitting element LD disposed in the third sub-pixel SPX3, and may overlap some components of the third pixel circuit PXC3.

The pixel area PXA may include a dummy area DMA. For example, the dummy area DMA may be disposed between a partial area of the pixel area PXA in which the second pixel circuit PXC2 is disposed and a partial area in the pixel area PXA in which the third pixel circuit PXC3 is disposed, but is not limited thereto.

A dummy wire DML and a dummy pattern DMP may be disposed in the dummy area DMA.

The dummy wire DML may extend into second direction DR2, and may be disposed between the second data line D2 and the third data line D3. The dummy wire DML may be disposed to be spaced apart from each of the second and third data lines D2, and D3. A plurality of dummy wires DML may be provided in the display area DA. The dummy wire DML may be electrically connected to the fourth power wire (refer to “PL4” in FIG. 4). Accordingly, the second power voltage VSS may be applied to the dummy wire DML. The dummy wire DML may be configured of the fourth conductive layer CL4. For example, the dummy wire DML may be configured of a five-layered conductive pattern.

The dummy pattern DMP may be disposed in a partial area of the dummy wire DML. The dummy pattern DMP may be integrally formed with the dummy wire DML. Accordingly, the second power voltage VSS may also be applied to the dummy pattern DMP.

In the embodiment, the dummy pattern DMP may include a five-layered conductive pattern in which a first layer, a second layer, a third layer, a fourth layer, and a fifth layer including a conductive material are sequentially stacked. The dummy pattern DMP may have a larger width than the dummy wire DML in the first direction DR1. For example, the dummy wire DML may have a first width W1 of about 3 μm in the first direction DR1, and the dummy pattern DMP may have a second width W2 of about 9.5 μm in the first direction DR1, but are not limited thereto.

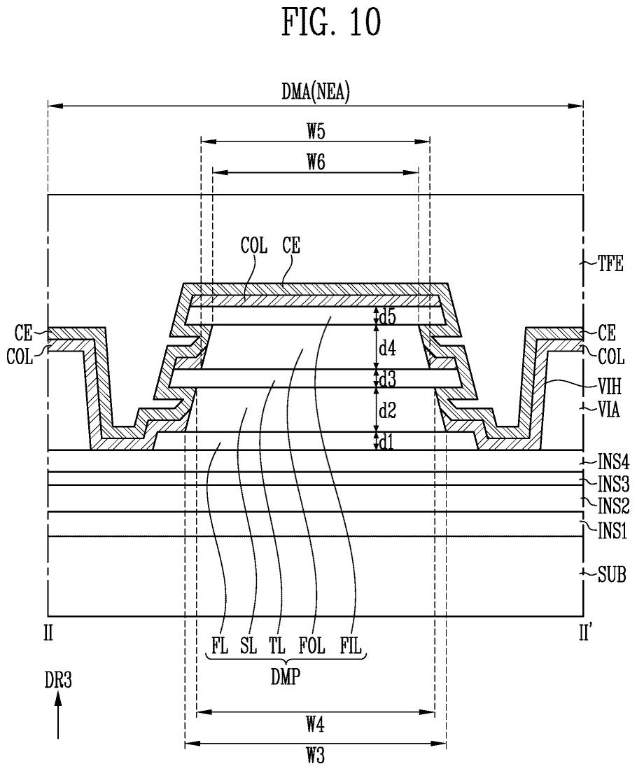

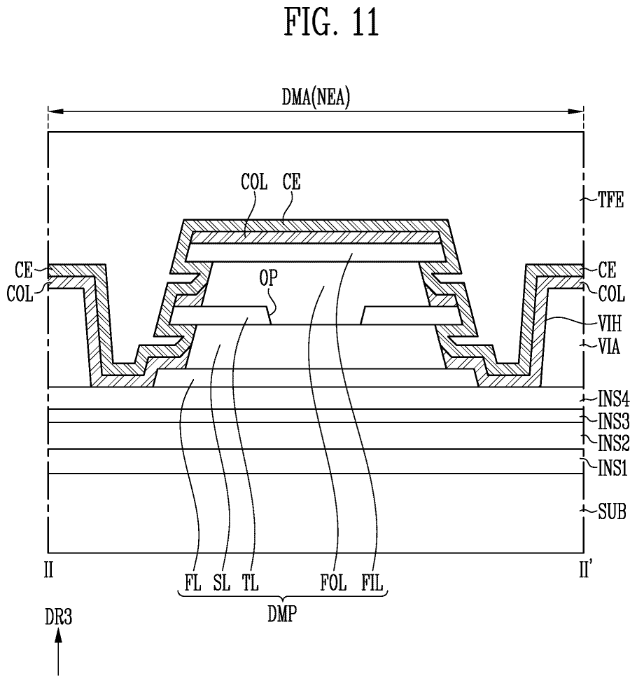

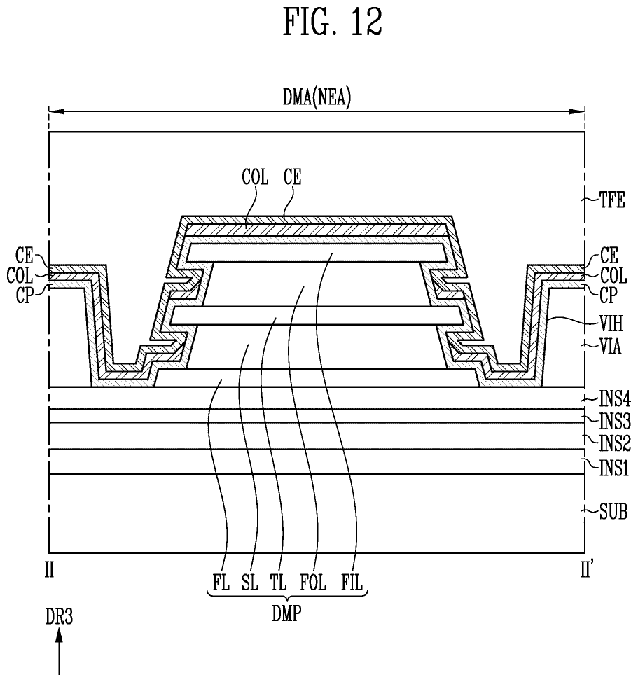

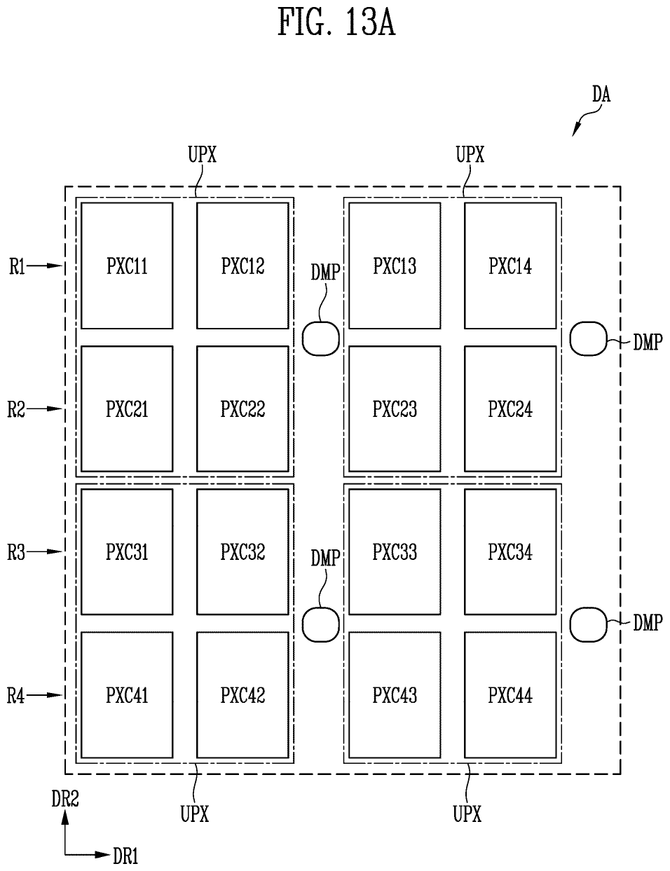

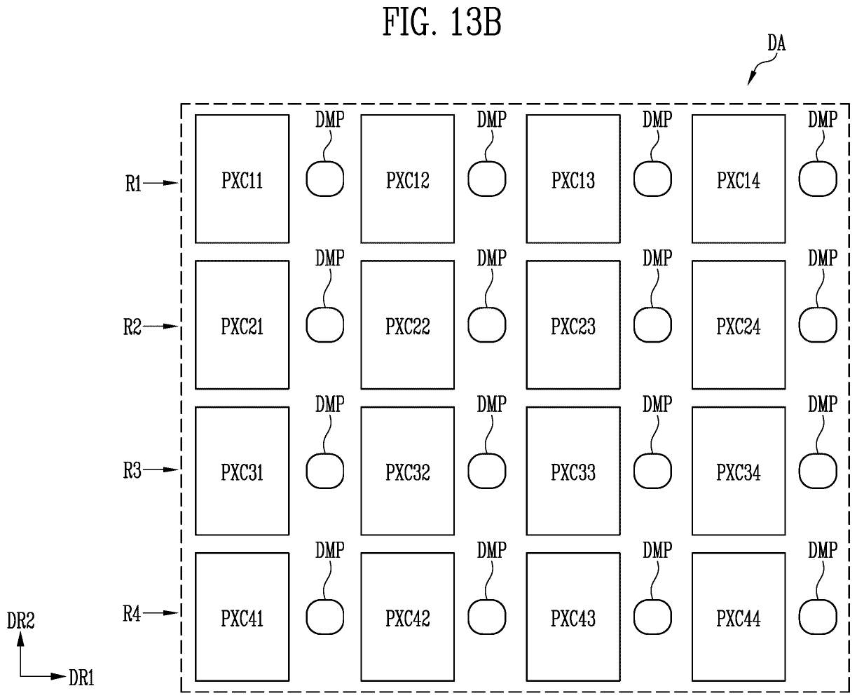

The dummy pattern DMP may be exposed to the outside through a via hole VIH formed in a via layer VIA which will be described hereinbelow. The dummy pattern DMP may be electrically connected to the common electrode (refer to “CE” in FIG. 9 and FIG. 10) to prevent voltage drop that may occur at the common electrode CE, thereby improving the reliability of each pixel PXL.

A detailed description of the above-described dummy pattern DMP will be described later with reference to FIG. 10 to FIG. 12.

Hereinafter, a stacked structure (or a cross-sectional structure) of the above-described pixel PXL will be mainly described with reference to FIG. 9.

FIG. 9 illustrates a schematic cross-sectional view taken along line I-I′ of FIG. 6.

In relation to the embodiment of FIG. 9, in order to avoid redundant descriptions, differences from the embodiment described above will be mainly described.

Referring to FIG. 1 to FIG. 9, the pixel PXL may include a first sub-pixel SPX1, a second sub-pixel SPX2, and a third sub-pixel SPX3 that are disposed adjacent to each other.

Each of the first to third sub-pixels SPX1, SPX2, and SPX3 may include a substrate SUB, a pixel circuit layer PCL, a display element layer DPL, and an encapsulation layer TFE.

The substrate SUB may include a transparent insulating material to transmit light. The substrate SUB may be a rigid substrate or a flexible substrate.

In the pixel circuit layer PCL, first to third pixel circuits PXC1, PXC2, and PXC3, and signal wires may be disposed. The light emitting element (refer to “LD” in FIG. 4) electrically connected to each of the first to third pixel circuits PXC1, PXC2, and PXC3 may be disposed in the display element layer DPL.

At least one or more insulating layers may be disposed on the substrate SUB. For example, a first insulating layer INS1, a second insulating layer INS2, a third insulating layer INS3, a fourth insulating layer INS4, a fifth insulating layer INS5, and a via layer VIA sequentially stacked along a third direction DR3 may be disposed on the substrate SUB. For example, at least one conductive layer may be disposed on the substrate SUB. For example, the conductive layer may include the first conductive layer CL1, the second conductive layer CL2, the third conductive layer CL3, the fourth conductive layer CL4, and the fifth conductive layer CL5. The first conductive layer CL1 may be disposed between the substrate SUB and the first insulating layer INS1, the second conductive layer CL2 may be disposed on the second insulating layer INS2, the third conductive layer CL3 may be disposed on the third insulating layer INS3, the fourth conductive layer CL4 may be disposed on the fourth insulating layer INS4, and the fifth conductive layer CL5 may be disposed on the via layer VIA.

The first conductive layer CL1 may include the first to seventh lower metal patterns BML1, BML2, BML3, BML4, BML5, BML6, and BML7. The second conductive layer CL2 may include the second power wire PL2, the first scan line S1i, the second scan line S2i, the third scan line S3i, the light emitting control line Ei, the third power wire PL3, the first gate electrode GE1, the first lower electrode LE1, and the additional conductive pattern ACP. The third conductive layer CL3 may include the first upper electrode UE1 and the second lower electrode LE2. The fourth conductive layer CL4 includes the first to twelfth connection patterns CNP1 to CNP12, the first to third data lines D1, D2, and D3, the first power wire PL1, the second upper electrode UE2, the dummy wire DML, and the dummy pattern DMP. The fifth conductive layer CL5 may include the first pixel electrode PE1, the second pixel electrode PE2, and the third pixel electrode (refer to “PE3” in FIG. 6).

In the embodiment, the fourth conductive layer CL4 may be configured as a five-layered conductive layer. For example, each of the third and seventh connection patterns CNP3 and CNP7 configured of the fourth conductive layer CL4 may include the first metal layer ML1, the second metal layer ML2, the third metal layer ML3, the fourth metal layer ML4, and the fifth metal layer ML5 that are sequentially stacked. The first metal layer ML1, the third metal layer ML3, and the fifth metal layer ML5 may include the same conductive material as each other, and the second metal layer ML2 and the fourth metal layer ML4 may include a conductive material having material characteristics different from those of the first, third, and fifth metal layers ML1, ML3, and ML5. For example, each of the first, third, and fifth metal layers ML1, ML3, and ML5 may include titanium, and each of the second and fourth metal layers ML2 and ML4 may include aluminum. The first metal layer ML1 may be disposed on the fourth insulating layer INS4, the second metal layer ML2 may be disposed on the first metal layer ML1, the third metal layer ML3 may be disposed on the second metal layer ML2, the fourth metal layer ML4 may be disposed on the third metal layer ML3, and the fifth metal layer ML5 may be disposed on the fourth metal layer ML4.

The first metal layer ML1 of each of the third and seventh connection patterns CNP3 and CNP7 may be electrically connected to the sixth drain area DA6 of the sixth transistor T6 through the contact hole CH formed through the second to fourth insulating layers INS2, INS3, and INS4. The fifth metal layer ML5 of the third connection pattern CNP3 may be electrically connected to the first pixel electrode PE1 through the first contact portion CNT1 formed in the via layer VIA, and the fifth metal layer ML5 of the seventh connection pattern CNP7 may be electrically connected to the second pixel electrode PE2 through the second contact portion CNT2 formed in the via layer VIA.

In the embodiment, the second metal layer ML2 is disposed between the first metal layer ML1 and the third metal layer ML3, and may have a side surface recessed from the side surface of each of the first and third metal layers ML1 and ML3. In this case, each of the first and third metal layers ML1 and ML3 may protrude from the side surface of the second metal layer ML2. In case that viewed in a cross-sectional view, a width of the second metal layer ML2 may be smaller than that of the first metal layer ML1 and that of the third metal layer ML3. The fourth metal layer ML4 is disposed between the third metal layer ML3 and the fifth metal layer ML5, and may have a side surface recessed from the side surface of each of the third and fifth metal layers ML3 and ML5. In this case, each of the third and fifth metal layers ML3 and ML5 may protrude from the side surface of the fourth metal layer ML4. However, it is not limited thereto, and in some embodiments, the first, second, third, fourth, and fifth metal layers ML1, ML2, ML3, ML4, and ML5 may have side surfaces disposed on the same line.

The pixel circuit layer PCL may be disposed on the substrate SUB. The above-described first to fifth insulating layers INS1, INS2, INS3, INS4, and INS5 may be disposed in the pixel circuit layer PCL.

The first insulating layer INS1 (or a buffer layer) may be entirely disposed on the substrate SUB. The first insulating layer INS1 may prevent diffusion of impurities into the first to seventh transistors T1, T2, T3, T4, T5, T6, and T7 included in the first to third pixel circuits PXC1, PXC2, and PXC3. The first insulating layer INS1 may be an inorganic insulating film including an inorganic material. For example, the first insulating layer INS1 may include at least one of a silicon nitride (SiNₓ), a silicon oxide (SiOₓ), and a silicon oxynitride (SiOₓN_{y}), or may include at least one of metal oxides such as an aluminum oxide (AlₓO_{y}). The first insulating layer INS1 may be provided as a single layered film, and may be provided as a multi-layered film including at least two or more films. In case that the first insulating layer INS1 is provided as the multi-layered film, respective layers thereof may be made of the same material or different materials. The first insulating layer INS1 may be omitted depending on the material, a process condition, and the like of the substrate SUB.

The second insulating layer INS2 (or the first gate insulating layer) may be entirely disposed on the first insulating layer INS1. The second insulating layer INS2 may include the same material as the first insulating layer INS1 described above, or may include a material suitable (or selected) from materials exemplified as constituent materials of the first insulating layer INS1. For example, the second insulating layer INS2 may include an inorganic insulating film including an inorganic material. In some embodiments, the second insulating layer INS2 may be partially disposed on the first insulating layer INS1. For example, the second insulating layer INS2 may be etched together with a base material of the second conductive layer CL2 during a manufacturing process of the second conductive layer C2 so that the second insulating layer INS2 is disposed only under the second conductive layer CL2. In this case, the second insulating layer INS2 may have the same width as the second conductive layer CL2 disposed thereon, but is not limited thereto.

The third insulating layer INS3 (or the second gate insulating layer) may be entirely provided and/or formed on the second insulating layer INS2. The third insulating layer INS3 may include the same material as the first insulating layer INS1, or may include one or more materials suitable (or selected) from materials exemplified as constituent materials of the first insulating layer INS1. For example, the third insulating layer INS3 may be an inorganic insulating film including an inorganic material.

The fourth insulating layer INS4 (or the interlayer insulating layer) may be entirely provided and/or formed on the third insulating layer INS3. The fourth insulating layer INS4 may include the same material as the first insulating layer INS1, or may include one or more materials suitable (or selected) from materials exemplified as constituent materials of the first insulating layer INS1.

The fifth insulating layer INS5 (or the passivation layer) may be entirely provided and/or formed on the fourth insulating layer INS4. The fifth insulating layer INS5 may be an inorganic insulating film including an inorganic material. The fifth insulating layer INS5 may include an opening corresponding to each of the contact portions CNT of the via layer VIA to expose a portion of the fourth conductive layer CL4 disposed thereunder.

The via layer VIA may be entirely provided and/or formed on the fifth insulating layer INS5 except contact hole CNT forming regions and via hole VIH forming regions. The via layer VIA may be configured as a single layer including an organic film or a multilayer including a double layer or more. In some embodiments, the via layer VIA may include an inorganic film and an organic film disposed on the inorganic film. In case that the via layer VIA is provided as a multilayer of a double layer or more, the organic film configuring the via layer VIA may be disposed as the uppermost layer. The via layer VIA may be at least one of a polyacrylates resin, an epoxy resin, a phenolic resin, a polyamides resin, a polyimides rein, an unsaturated polyesters resin, a poly-phenylene ethers resin, a poly-phenylene sulfides resin, and a benzocyclobutene resin.

In the embodiment, the via layer VIA may include contact portions CNT exposing some of the circuit elements disposed on the pixel circuit layer PCL. For example, the via layer VIA may include a first contact portion CNT1, a second contact portion CNT2, and a third contact portion CNT3. The first contact portion CNT1 may expose a partial area of the third connection pattern CNP3, the second contact portion CNT2 may expose a partial area of the seventh connection pattern CNP7, and the third contact portion CNT3 may expose a partial area of the eleventh connection pattern CNP11. In the embodiment, the via layer VIA may include a via hole VIH exposing the dummy pattern DMP.

The pixel circuit layer PCL of each of the first to third sub-pixels SPX1, SPX2, and SPX3 may include the first to seventh transistors T1 to T7, the storage capacitor Cst, and the additional capacitor Cad disposed on the first insulating layer INS1.

The first transistor T1 may include th first active pattern ACT1, the first source area SA1, and the first drain area DA1 disposed on the first insulating layer INS1, and the first gate electrode GE1 disposed on the second insulating layer INS2. The first lower metal pattern BML1 may be disposed under the first gate electrode GE1 and the first active pattern ACT1 with the first insulating layer INS1 interposed therebetween.

The second transistor T2 may include the second active pattern ACT2, the second source area SA2, and the second drain area DA2 disposed on the first insulating layer INS1, and the second gate electrode GE2 disposed on the second insulating layer INS2. The second lower metal pattern BML2 may be disposed under the second gate electrode GE2 (or the first scan line S1i) and the second active pattern ACT2 with the first insulating layer INS1 interposed therebetween.

The (3a)-th transistor T3a may include the (3a)-th active pattern ACT3a, the (3a)-th source area SA3a, and the (3a)-th drain area DA3a disposed on the first insulating layer INS1, and the (3a)-th gate electrode GE3a disposed on the second insulating layer INS2. The (3b)-th transistor T3b may include the (3b)-th active pattern ACT3b, the (3b)-th source area SA3b, and the (3b)-th drain area DA3b disposed on the first insulating layer INS1, and the (3b)-th gate electrode GE3b disposed on the second insulating layer INS2. The third lower metal pattern BML3 may be disposed under the (3a)-th and (3b)-th gate electrodes GE3a and GE3b (or the first scan line S1i) and the (3a)-th and (3b)-th active patterns ACT3a and ACT3b with the first insulating layer INS1 interposed therebetween.

The (4a)-th transistor T4a may include the (4a)-th active pattern ACT4a, the (4a)-th source area SA4a, and the (4a)-th drain area DA4a disposed on the first insulating layer INS1, and the (4a)-th gate electrode GE4a disposed on the second insulating layer INS2. The (4b)-th transistor T4b may include the (4b)-th active pattern ACT4b, the (4b)-th source area SA4b, and the (4b)-th drain area DA4b disposed on the first insulating layer INS1, and the (4b)-th gate electrode GE4b disposed on the second insulating layer INS2. The fourth lower metal pattern BML4 may be disposed under the (4a)-th and (4b)-th gate electrodes GE4a and GE4b (or the second scan line S2i) and the (4a)-th and (4b)-th active patterns ACT4a and ACT4b with the first insulating layer INS1 interposed therebetween.

The fifth transistor T5 may include th fifth active pattern ACT5, the fifth source area SA5, and the fifth drain area DA5 disposed on the first insulating layer INS1, and the fifth gate electrode GE5 disposed on the second insulating layer INS2. The fifth lower metal pattern BML5 may be disposed under the fifth gate electrode GE5 (or the light emitting control line Ei) and the fifth active pattern ACT5 with the first insulating layer INS1 interposed therebetween.

The sixth transistor T6 may include the sixth active pattern ACT6, the sixth source area SA6, and the sixth drain area DA6 disposed on the first insulating layer INS1, and the sixth gate electrode GE6 disposed on the second insulating layer INS2. The sixth lower metal pattern BML6 may be disposed under the sixth gate electrode GE6 (or the light emitting control line Ei) and the sixth active pattern ACT6 with the first insulating layer INS1 interposed therebetween. In the first sub-pixel SPX1, the sixth drain area DA6 may be electrically connected to the third connection pattern CNP3 through the contact hole CH formed through the second to fourth insulating layers INS2, INS3, and INS4. In the second sub-pixel SPX2, the sixth drain area DA6 may be electrically connected to the seventh connection pattern CNP7 through the contact hole CH formed through the second to fourth insulating layers INS2, INS3, and INS4.

The (7a)-th transistor T7a may include the (7a)-th active pattern ACT7a, the (7a)-th source area SA7a, and the (7a)-th drain area DA7a disposed on the first insulating layer INS1, and the (7a)-th gate electrode GE7a disposed on the second insulating layer INS2. The (7b)-th transistor T7b may include the (7b)-th active pattern ACT7b, the (7b)-th source area SA7b, and the (7b)-th drain area DA7b disposed on the first insulating layer INS1, and the (7b)-th gate electrode GE7b disposed on the second insulating layer INS2. The seventh lower metal pattern BML7 may be disposed under the (7a)-th and (7b)-th gate electrodes GE7a and GE7b (or the third scan line S3i) and the (7a)-th and (7b)-th active patterns ACT7a and ACT7b with the first insulating layer INS1 interposed therebetween.

The storage capacitor Cst may include the first lower electrode LE1 disposed on the second insulating layer INS2 and the first upper electrode UE1 disposed on the third insulating layer INS3 to overlap the first lower electrode LE1 in a plan view.

The additional capacitor Cad may include the second lower electrode LE2 disposed on the third insulating layer INS3 and the second upper electrode UE2 disposed on the fourth insulating layer INS4 to overlap the second lower electrode LE2 in a plan view.

The display element layer DPL may be disposed on the pixel circuit layer PCL. The display element layer DPL may include the light emitting element LD and the pixel defining film PDL. For example, the light emitting element LD may include a first light emitting element LD1 electrically connected to the first pixel circuit PXC1, a second light emitting element LD2 electrically connected to the second pixel circuit PXC2, and a third light emitting element electrically connected to the third pixel circuit PXC3. The first light emitting element LD1 may be disposed on the display element layer DPL of the first sub-pixel SPX1, the second light emitting element LD2 may be disposed on the display element layer DPL of the second sub-pixel SPX2, and the third light emitting element may be disposed on the display element layer DPL of the third sub-pixel SPX3.

The first light emitting element LD1 may include the first pixel electrode PE1 (the anode or first electrode), the first light emitting layer EML1, and the common electrode CE (the cathode or second electrode). The second light emitting element LD2 may include the second pixel electrode PE2 (the anode or first electrode), the second light emitting layer EML2, and the common electrode CE (the cathode or second electrode). The third light emitting element may include the third pixel electrode PE3 (the anode or first electrode), the third light emitting layer (refer to “EML3” in FIG. 3), and the common electrode CE (the cathode or second electrode).

The first pixel electrode PE1 may be electrically connected to the third connection pattern CPN3 through the first contact portion CNT1. The second pixel electrode PE2 may be electrically connected to the seventh connection pattern CNP7 through the second contact portion CNT2.

Each of the first pixel electrode PE1, the second pixel electrode PE2, and the third pixel electrode PE3 may be made of a conductive material (or substance). The conductive material may include an opaque metal. The opaque metal may include, for example, silver, magnesium, aluminum, platinum, palladium, gold, nickel, neodymium, iridium, chromium, titanium, or an alloy thereof. However, a material of each of the first pixel electrode PE1, the second pixel electrode PE2, and the third pixel electrode PE3 is not limited to the above-described example. In some embodiments, the first pixel electrode PE1, the second pixel electrode PE2, and the third pixel electrode PE3 may include a transparent conductive material (or substance). The transparent conductive material (or substance) may include a conductive oxide such as an indium tin oxide (ITO), an indium zinc oxide (IZO), a zinc oxide (ZnOx), an indium gallium zinc oxide (IGZO), and an indium tin zinc oxide (ITZO), and a conductive polymer such as poly(3,4-ethylenedioxythiophene (PEDOT). In case that the first pixel electrode PE1, the second pixel electrode PE2, and the third pixel electrode PE3 include a transparent conductive material (or substance), a separate conductive layer made of an opaque metal for reflecting light emitted from the first light emitting layer EML1, the second light emitting layer EML2, and the third light emitting layer (refer to “EML3” in FIG. 3) to the image display direction of the display device DD (or the upward direction of the encapsulation layer TFE) may be added. For example, each of the first, second, and third pixel electrodes PE1, PE2, and PE3 may be configured of a triple layered film of ITO/Ti/ITO.

The first pixel electrode PE1 may be disposed in at least first emission area EMA1, the second pixel electrode PE2 may be disposed in at least second emission area EMA2, and the third pixel electrode PE3 may be disposed in at least third emission area (refer to “EMA3” in FIG. 3).

The pixel defining film PDL is provided on the pixel circuit layer PCL in the non-emission area NEA, and may define (or partition) the first emission area EMA1, the second emission area EMA2, and the third emission area EMA3. The pixel defining film PDL may include an organic insulating film made of an organic material. The organic material may include an acryl resin, an epoxy resin, a phenolic resin, a polyamide resin, a polyimide resin, or the like. In some embodiments, the pixel defining film PDL may include a light absorbing material, or may serve to absorb light introduced from the outside by a light absorbing agent being applied thereon. For example, the pixel defining film PDL may include a carbon-based black pigment, but is not limited thereto.

The pixel defining film PDL includes an opening exposing a partial area of each of the first pixel electrode PE1, the second pixel electrode PE2, and the third pixel electrode PE3, and may protrude from the via layer VIA along the circumference of each of the first to third emission areas EMA1, EMA2, and EMA3 in the third direction DR3.

The first light emitting layer EML1 may be disposed on the first pixel electrode PE1 exposed by one opening of the pixel defining film PDL, the second light emitting layer EML2 may be disposed on the second pixel electrode PE2 exposed by another opening of the pixel defining film PDL, and the third light emitting layer EML3 may be disposed on the third pixel electrode PE3 exposed by the other opening of the pixel defining film PDL.

The first light emitting layer EML1 may be disposed on the first pixel electrode PE1 within the one opening of the pixel defining film PDL, the second light emitting layer EML2 may be disposed on the second pixel electrode PE2 within the another opening of the pixel defining film PDL, and the third light emitting layer EML3 may be disposed on the third pixel electrode PE3 within the other opening of the pixel defining film PDL. Each of the first light emitting layer EML1, the second light emitting layer EML2, and the third light emitting layer EML3 may be formed in the openings of the pixel defining film PDL by an inkjet printing method or the like, but is not limited thereto.

Each of the first light emitting layer EML1, the second light emitting layer EML2, and the third light emitting layer EML3 may include a light generation layer for generating light. For example, the first light emitting layer EML1 may include a light generation layer that generates and emits red light, the second light emitting layer EML2 may include a light generation layer that generates and emits green light, and the third light emitting layer EML3 may include a light generation layer that generates and emits blue light, but are not limited thereto. In some embodiments, each of the first light emitting layer EML1, the second light emitting layer EML2, and the third light emitting layer EML3 may include a light generation layer that generates and emits white light or blue light, and in this case, a color conversion layer for converting the white light or the blue light (for example, the first color light) into a specific color light (for example, the second color light) may be provided.

A control layer COL and a common electrode CE may be disposed on the first and second light emitting layers EML1 and EML2 and the pixel defining film PDL.

The control layer COL may be disposed between each of the first and second pixel electrodes PE1 and PE2 and the common electrode CE. The control layer COL may be disposed adjacent to each of the first and second light emitting layers EML1 and EML2. The control layer COL may improve the luminous efficiency and life-span of the first and second light emitting elements LD1 and LD2 by controlling the movement of charge. The control layer COL may include at least one of a hole transport material, a hole injection material, an electron transport material, and an electron injection material. In FIG. 9, it is shown that the control layer COL is disposed between each of the first and second light emitting layers EML1 and EML2 and the common electrode CE, but is not limited thereto. In some embodiments, the control layer COL may be disposed between the first light emitting layer EML1 and the first pixel electrode PE1 and between the second light emitting layer EML2 and the second pixel electrode PE2, respectively. The control layer COL may be provided as a plurality of layers stacked along the third direction DR3 with the first and second light emitting layers EML1 and EML2 interposed therebetween. The control layer COL may be commonly provided in the first to third sub-pixels SPX1, SPX2, and SPX3.

The common electrode CE may be disposed on the first and second light emitting layers EML1 and EML2. The common electrode CE may be commonly provided in the first to third sub-pixels SPX1, SPX2, and SPX3. The common electrode CE may be provided in a plate shape in the entire area of the display area DA, but is not limited thereto. The common electrode CE may be a thin metal layer having a thickness sufficient to transmit light emitted from the first and second light emitting layers EML1 and EML2. The common electrode CE may be made of a metallic material or a transparent conductive material to have a relatively thin thickness. For example, the common electrode CE may include at least one of various transparent conductive materials including an indium tin oxide, an indium zinc oxide, an indium tin zinc oxide, an aluminum zinc oxide, a gallium zinc oxide, a zinc tin oxide, and a gallium tin oxide, and may be realized to be substantially transparent or translucent to satisfy a predetermined light transmittance. Accordingly, the light emitted from each of the first and second light emitting layers EML1 and EML2 disposed below the common electrode CE may pass through the common electrode CE to be emitted in the upper direction of the encapsulation layer TFE.

Although not directly shown in the drawing, the common electrode CE may be electrically connected to the fourth power wire (refer to “PL4” in FIG. 4). Accordingly, the common electrode CE may be supplied with the same voltage as the dummy wire DML and the dummy pattern DMP, for example, the second power voltage VSS (or low potential voltage).

The encapsulation layer TFE may include a first encapsulation layer ENC1, a second encapsulation layer ENC2, and a third encapsulation layer ENC3 sequentially disposed on the common electrode CE. The first encapsulation layer ENC1 may be formed on the display element layer DPL (or the common electrode CE), and may be disposed in at least a portion of the display area DA and the non-display area NDA. The second encapsulation layer ENC2 may be formed on the first encapsulation layer ENC1, and may be disposed in at least some of the display area DA and the non-display area NDA. The third encapsulation layer ENC3 may be formed on the second encapsulation layer ENC2, and may be disposed in at least some of the display area DA and the non-display area NDA. In some embodiments, the third encapsulation layer ENC3 may be disposed to entirely overlap the display area DA and the non-display area NDA.

Each of the first and third encapsulation layers ENC1 and ENC3 may be formed of an inorganic film including an inorganic material, and the second encapsulation layer ENC2 may be formed of an organic film including an organic material. The inorganic film is, for example, a silicon nitride (SiNₓ), a silicon oxide (SiOₓ), or a silicon oxynitride (SiOₓN_{y}), and the like. The organic film may include an organic insulating material such as a polyacrylates resin, an epoxy resin, a phenolicresin, a polyamides resin, a polyimides rein, an unsaturated polyesters resin, a poly phenylenethers resin, a polyphenylenesulfides resin, or benzocyclobutene (BCB).

In some embodiments, a color filter layer and/or a color conversion layer for emitting light emitted from the first and second light emitting elements LD1 and LD2 as light having excellent color reproducibility may be selectively provided and/or formed on the encapsulation layer TFE.

Hereinafter, the dummy pattern DMP disposed in the dummy area DMA will be described in detail with reference to FIG. 10 to FIG. 12.

FIG. 10 to FIG. 12 illustrate schematic cross-sectional views taken along line II-II′ of FIG. 6.

FIG. 11 and FIG. 12 illustrate variations of FIG. 10 in relation to the shape of the dummy pattern DMP.

In relation to the embodiments of FIG. 10 to FIG. 12, differences from the above-described embodiment will be mainly described in order to avoid duplicate descriptions.

Referring to FIG. 5 to FIG. 12, the dummy pattern DMP may be disposed on the fourth insulating layer INS4 in the dummy area DMA (or the non-emission area NEA).

In the embodiment, the dummy pattern DMP may be configured of the fourth conductive layer CL4. The dummy pattern DMP may be configured of a five-layered film including a first layer FL, a second layer SL, a third layer TL, a fourth layer FOL, and a fifth layer FL sequentially stacked along the third direction DR3. The first layer FL may be disposed on the fourth insulating layer INS4, the second layer SL may be disposed on the first layer FL, the third layer TL may be disposed on the second layer SL, the fourth layer FOL may be disposed on the third layer TL, and the fifth layer FIL may be disposed on the fourth layer FOL.

The first layer FL, the third layer TL, and the fifth layer FIL may include the same material. For example, the first layer FL, the third layer TL, and the fifth layer FIL may include titanium. The first layer FL may include the same material as the first metal layer ML1 of each of the third and seventh connection patterns CNP3 and CNP7, and may be disposed on the same layer. The third layer TL may include the same material as the third metal layer ML3 of each of the third and seventh connection patterns CNP3 and CNP7, and may be disposed on the same layer. The fifth layer FIL may include the same material as the fifth metal layer ML5 of each of the third and seventh connection patterns CNP3 and CNP7, and may be disposed on the same layer.

The second layer SL and the fourth layer FOL may include a conductive material having material characteristics different from those of the first, third, and fifth layers FL, TL, and FIL. For example, the second layer SL and the fourth layer FOL may include aluminum. The second layer SL may include the same material as the second metal layer ML2 of each of the third and seventh connection patterns CNP3 and CNP7, and may be disposed on the same layer. The fourth layer FOL may include the same material as the fourth metal layer ML4 of each of the third and seventh connection patterns CNP3 and CNP7, and may be disposed on the same layer.

The first layer FL may have a first thickness d1 (or a first height) in the third direction DR3, the second layer SL may have a second thickness d2 (or a second height) in the third direction DR3, the third layer TL may have a third thickness d3 (or a third height) in the third direction DR3, the fourth layer FOL may have a fourth thickness d4 (or a fourth height) in the third direction DR3, and the fifth layer FIL may have a fifth thickness d5 (or a fifth height) in the third direction DR3

The first thickness d1, the second thickness d2, the third thickness d3, the fourth thickness d4, and the fifth thickness d5 may be different from each other. The second thickness d2 and the fourth thickness d4 may be thicker (or larger) than the first thickness d1, the third thickness d3, and the fifth thickness d5. For example, the first thickness d1 may be about 700 Å, the second thickness d2 may be about 6000 Å, the third thickness d3 may be about 300 Å, the fourth thickness d4 may be about 4000 Å, and the fifth thickness d5 may be about 300 Å, but are not limited thereto. In some embodiments, the first thickness d1, the third thickness d3, and the fifth thickness d5 may be the same, and the second thickness d2 and the fourth thickness d4 may be the same.

The second layer SL may include a lower surface in contact with the first layer FL and an upper surface in contact with the third layer TL. The second layer SL may have a polygonal shape, for example, a trapezoidal shape in a cross-sectional view, the width of which decreases from the lower surface toward the upper surface along the third direction. A width W3 of the lower surface of the second layer SL may be about 10 μm to 13 μm, and a width W4 of the upper surface of the second layer SL may be about 9 μm, but are not limited thereto.

A side surface of the second layer SL may be recessed from a side surface of each of the first and third layers FL and TL. In this case, each of the first and third layers FL and TL may protrude from the side surface of the second layer SL. Particularly, the second layer SL may have an undercut portion disposed under the third layer SL or the third layer SL may have eaves protruding from the side surface of the second layer SL in a cross-sectional view.

The fourth layer FOL may include a lower surface in contact with the third layer TL and an upper surface in contact with the fifth layer FIL. The fourth layer FOL may have a polygonal shape, for example, a trapezoidal shape in a cross-sectional view, the width of which decreases from the lower surface toward the upper surface along the third direction DR3. A width W5 of the lower surface of the fourth layer FOL may be about 10 μm to 13 μm, and a width W6 of the upper surface of the fourth layer FOL may be about 9 μm, but are not limited thereto. In some embodiments, the width W3 of the lower surface of the second layer SL and the width W5 of the lower surface of the fourth layer FOL may be the same or different from each other. For example, the width W4 of the upper surface of the second layer SL and the width W6 of the upper surface of the fourth layer FOL may be the same or different from each other.

A side surface of the fourth layer FOL may be recessed from a side surface of each of the third and fifth layers TL and FIL. In this case, each of the third and fifth layers TL and FIL may protrude from the side surface of the fourth layer FOL. Particularly, the fourth layer FOL disposed on the third layer TL may have an undercut portion disposed under the fifth layer FIL or the fifth layer FIL may have eaves protruding from the side surface of the fourth layer FOL in a cross-sectional view.

As described above, since the third layer TL has eaves protruding from the side surface of the second layer SL disposed thereunder and the fifth layer FIL has eaves protruding from the side surface of the fourth layer FOL disposed thereunder, the dummy pattern DMP may have a double eaves structure.

The dummy pattern DMP may be exposed to the outside through the via hole VIH in the via layer VIA.

The control layer COL may be disposed on the dummy pattern DMP. The control layer COL may be the control layer COL described with reference to FIG. 9.

A portion of the control layer COL commonly provided to the first to third sub-pixels SPX1, SPX2, and SPX3 may be disconnected by the dummy pattern DMP in the via hole VIH of the dummy area DMA. In other words, the control layer COL may include a disconnection portion (or an open portion) on the dummy pattern DMP. The disconnection portion may be an open portion in which the control layer COL is not continuously formed due to the dummy pattern DMP in the via hole VIH.

The control layer COL may be formed on the dummy pattern DMP by an inkjet printing method. As the dummy pattern DMP has a double eaves structure, the control layer COL may be formed only on an upper surface of the fifth layer FIL, a lower end portion of a side surface of the fourth layer FOL, an upper surface of the third layer TL, a lower end portion of a side surface of the second layer SL, and the first layer FL, and may not be formed on an upper end portion of a side surface of the fourth layer FOL covered by the fifth layer FIL and an upper end portion of a side surface of the second layer SL covered by the third layer TL. Accordingly, the control layer COL may be separated (or disconnected) in the via hole VIH due to undercut portions in the dummy pattern DMP in the second layer SL and the fourth layer FOL.

The common electrode CE may be disposed on the control layer COL. The common electrode CE may be the common electrode CE described with reference to FIG. 9.

The common electrode CE commonly provided to the first to third sub-pixels SPX1, SPX2, and SPX3 may be formed on the control layer COL by a sputtering method. For example, the common electrode CE may be formed on an upper end portion of a side surface of the fourth layer FOL in which the control layer COL is not formed and an upper end portion of a side surface of the second layer SL. Since the common electrode CE is formed by the sputtering method, the movement direction of the particles may be random, and compared to the control layer COL, it may be relatively less affected by an incident angle difference according to the position of the pixels PXL (or display panel DP) and/or process distribution. Accordingly, the common electrode CE may also be formed on an upper end portion of a side surface of each of the second and fourth layers SL and FOL of the dummy pattern DMP exposed to the outside by the disconnection portion of the control layer COL. In this case, the contact area between the conductive dummy pattern DMP and the common electrode CE may increase. As the contact area between the dummy pattern DMP and the common electrode CE increases, reliability of the display device (refer to “DD” in FIG. 1) may be improved by improving the contact resistance of the common electrode CE to prevent a voltage drop of the common electrode CE.

For example, in the above-described embodiment, a process such as laser drilling for electrically connecting the cathode electrode and the driving power wire is omitted, and the common electrode CE and the dummy pattern DMP are electrically connected, so that manufacturing efficiency of the display device DD may be increased.

The encapsulation layer TFE may be disposed on the dummy pattern DMP. The encapsulation layer TFE may be the encapsulation layer TFE described with reference to FIG. 9.

An embodiment for further improving the contact resistance of the common electrode CE may be considered. For example, as shown in FIG. 11, the third layer TL of the dummy pattern DMP may include the opening OP, and may expose the second layer SL disposed therebelow to the outside. In this case, the second layer SL may directly contact the fourth layer FOL. In the embodiment, the second layer SL and the fourth layer FOL may be made of the same conductive material, for example, aluminum. As the second layer SL and the fourth layer FOL made of aluminum, which have a relatively smaller specific resistance than the first, third, and fifth layers FL, TL, and FIL made of titanium, are in direct contact and connected, the contact characteristics between the common electrode CE and the dummy pattern DMP respectively formed on the upper end portion of the side surface of the second layer SL and the upper end portion of the side surface of the fourth layer FOL to be connected to the second and fourth layers SL and FOL is improved, so that the contact resistance of the common electrode CE may be further improved.

In some embodiments, an additional conductive layer may be disposed on the dummy pattern DMP. For example, as shown in FIG. 12, the conductive pattern CP may be disposed on the dummy pattern DMP. The conductive pattern CP may be formed in the same process as the first and second pixel electrodes PE1 and PE2 described with reference to FIG. 9 and include the same material. For example, the conductive pattern CP may include a transparent conductive oxide.

The conductive pattern CP may be formed on the dummy pattern DMP to entirely surround the dummy pattern DMP. The conductive pattern CP including the transparent conductive oxide may be disposed on the first, third, and fifth layers FL, TL and FIL made of titanium and the second and fourth layers SL and FOL made of aluminum to cover the first to fifth layers FL, SL, TL, FOL, and FIL, thereby preventing oxidation that may occur due to material characteristics of each layer. For example, the conductive pattern CP may be disposed between the common electrode CE and the dummy pattern DMP to be electrically connected to each of the common electrode CE and the dummy pattern DMP. Accordingly, the contact resistance of the common electrode CE may be further improved.

FIG. 13A and FIG. 13B illustrate schematic plan views of one area of the display area DA included in the display device of FIG. 1. Particularly, FIG. 13A and FIG. 13B illustrate various embodiments of the disposition structure of the pixel circuits and the dummy patterns DMP.

Referring to FIG. 1, FIG. 13A, and FIG. 13B, a plurality of pixel circuits and dummy patterns DMP may be disposed in the display area DA of the display device DD.

The display area DA may include pixel rows R1 to R4. Each of the pixel rows R1 to R4 may extend in the first direction DR1, and may be arranged in the second direction DR2. Each of the pixel rows R1 to R4 may include pixel circuits.

In the first pixel row R1 (or the first horizontal line), an eleventh pixel circuit PXC11, a twelfth pixel circuit PXC12, a thirteenth pixel circuit PXC13, and a fourteenth pixel circuit PXC14 may be disposed. The eleventh pixel circuit PXC11 may be a pixel circuit of a first sub-pixel disposed in the first pixel row R1, the twelfth pixel circuit PXC12 may be a pixel circuit of a second sub-pixel disposed in the first pixel row R1, the thirteenth pixel circuit PXC13 may be a pixel circuit of a third sub-pixel disposed in the first pixel row R1, and the fourteenth pixel circuit PXC14 may be a pixel circuit of a fourth sub-pixel disposed in the first pixel row R1.

A twenty-first pixel circuit PXC21, a twenty-second pixel circuit PXC22, a twenty-third pixel circuit PXC23, and a twenty-fourth pixel circuit PXC24 may be disposed in the second pixel row R2 (or the second horizontal line). The twenty-first pixel circuit PXC21 may be a pixel circuit of a first sub-pixel disposed in the second pixel row R2, the twenty-second pixel circuit PXC22 may be a pixel circuit of a second sub-pixel disposed in the second pixel row R2, the twenty-third pixel circuit PXC23 may be a pixel circuit of a third sub-pixel disposed in the second pixel row R2, and the twenty-fourth pixel circuit PXC24 may be a pixel circuit of a fourth sub-pixel disposed in the second pixel row R2.

A thirty-first pixel circuit PXC31, a thirty-second pixel circuit PXC32, a thirty-third pixel circuit PXC33, and a thirty-fourth pixel circuit PXC34 may be disposed in the third pixel row R3 (or the third horizontal line). The thirty-first pixel circuit PXC31 may be a pixel circuit of a first sub-pixel disposed in the third pixel row R3, the thirty-second pixel circuit PXC32 may be a pixel circuit of a second sub-pixel disposed in the third pixel row R3, the thirty-third pixel circuit PXC33 may be a pixel circuit of a third sub-pixel disposed in the third pixel row R3, and the thirty-fourth pixel circuit PXC34 may be a pixel circuit of a fourth sub-pixel disposed in the third pixel row R3.

A forty-first pixel circuit PXC41, a forty-second pixel circuit PXC42, a forty-third pixel circuit PXC43, and a forty-fourth pixel circuit PXC44 may be disposed in the fourth pixel row R4 (or the fourth horizontal line). The forty-first pixel circuit PXC41 may be a pixel circuit of a first sub-pixel disposed in the fourth pixel row R4, the forty-second pixel circuit PXC42 may be a pixel circuit of a second sub-pixel disposed in the fourth pixel row R4, the forty-third pixel circuit PXC43 may be a pixel circuit of a third sub-pixel disposed the fourth pixel row R4, and the forty-fourth pixel circuit PXC44 may be a pixel circuit of a fourth sub-pixel disposed in the fourth pixel row R4.

In the display area DA, the dummy pattern DMP may be disposed with a density different from that of the pixel circuits. For example, as shown in FIG. 13A, one dummy pattern DMP per unit pixel block UPX may be disposed. The unit pixel block UPX may be a virtual unit block with a predetermined area including two pixel circuits adjacent in the first direction DR1 and two pixel circuits adjacent to the two pixel circuits in the second direction DR2 crossing the first direction DR1. The unit pixel block UPX may include, for example, the eleventh pixel circuit PXC11, the twelfth pixel circuit PXC12, the twenty-first pixel circuit PXC21, and the twenty-second pixel circuit PXC22. One dummy pattern DMP may be disposed per unit pixel block UPX including 2×2 pixel circuits, and the dummy pattern DMP may be disposed in a smaller number than the pixel circuits in the display area DA.

In the above-described embodiment, it has been described that the unit pixel block UPX includes 2×2 pixel circuits, but is not limited thereto. In some embodiments, the unit pixel block UPX may include 3×3 pixel circuits or 4×4 pixel circuits.

In some embodiments, the dummy pattern DMP within the display area DA may be disposed with the same density as the pixel circuits. For example, as shown in FIG. 13B, the same number of dummy patterns DMP as the pixel circuits may be disposed. In this case, the dummy pattern DMP may be disposed to form a one-to-one correspondence with the pixel circuits.

The arrangement structure of the pixel circuits and dummy pattern DMP is not limited to the above embodiment. That is, the density, number, and size of the pixel circuits and dummy pattern DMP in the display area DA may be variously changed within a range consistent with the concept of the present embodiment.

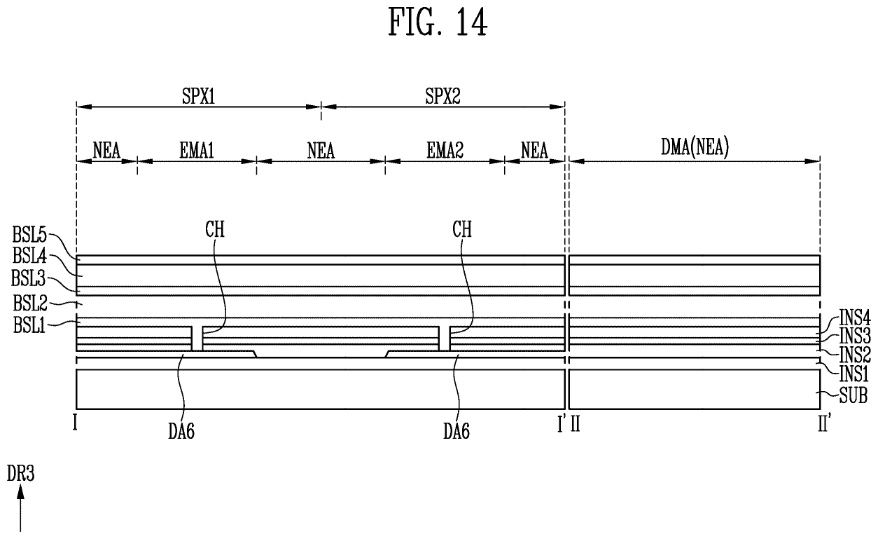

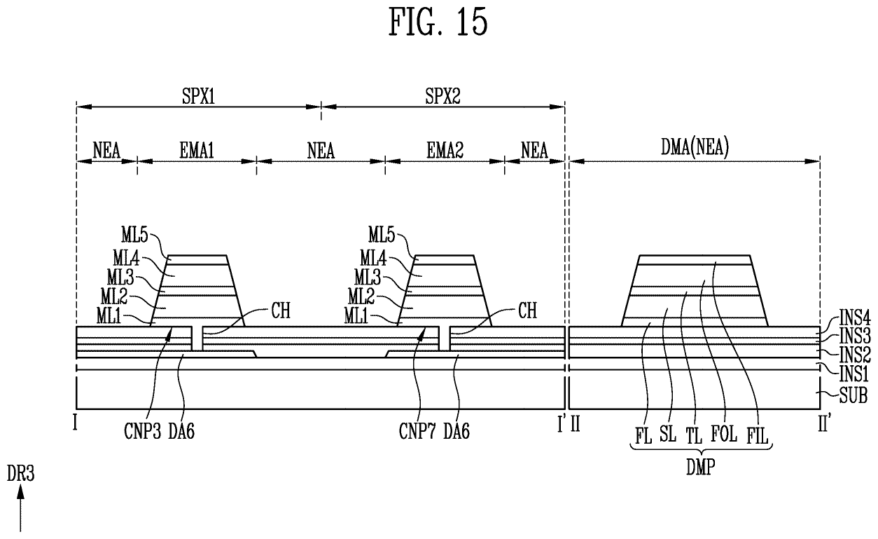

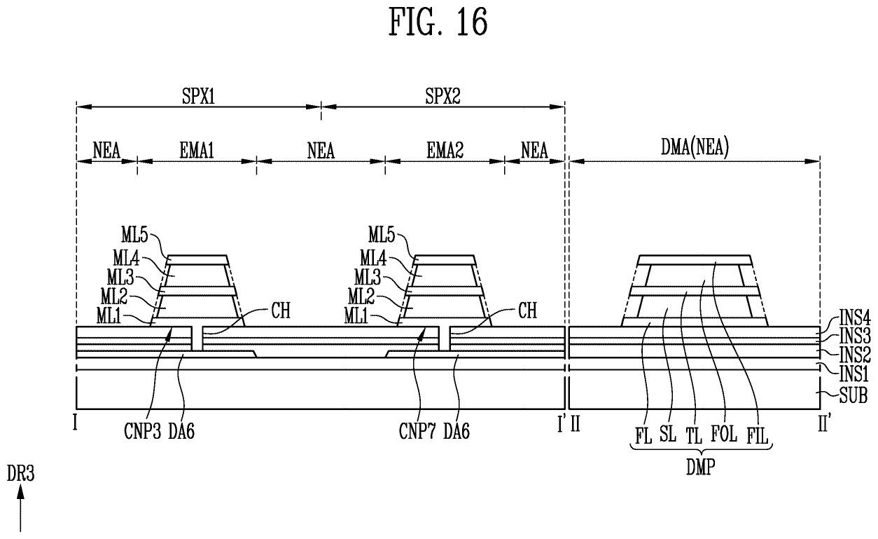

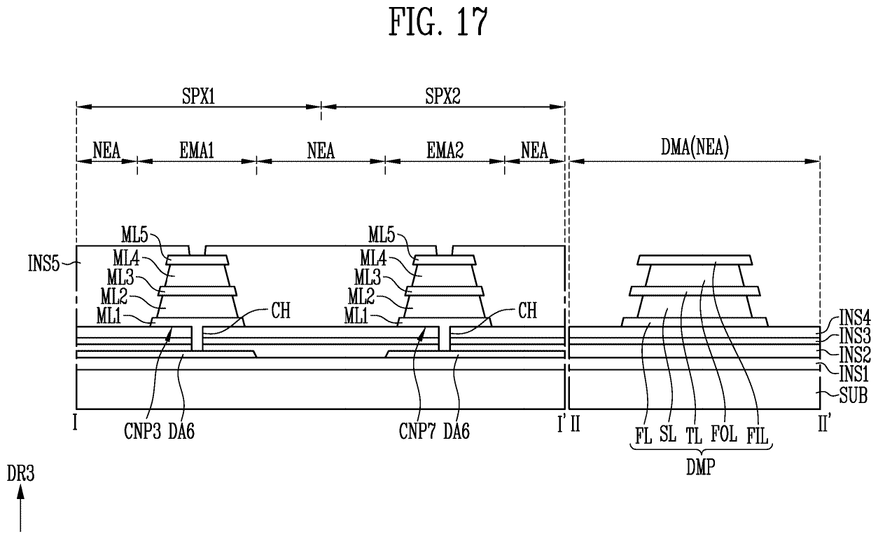

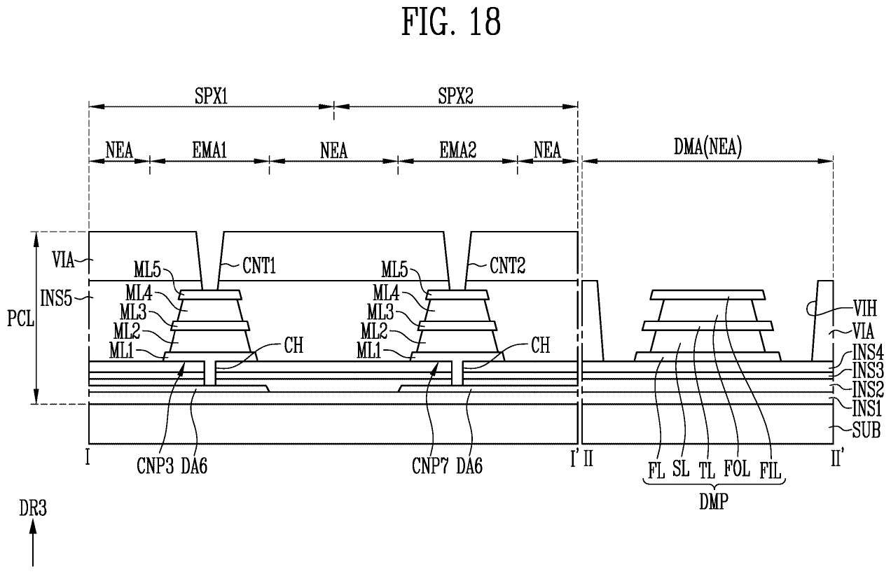

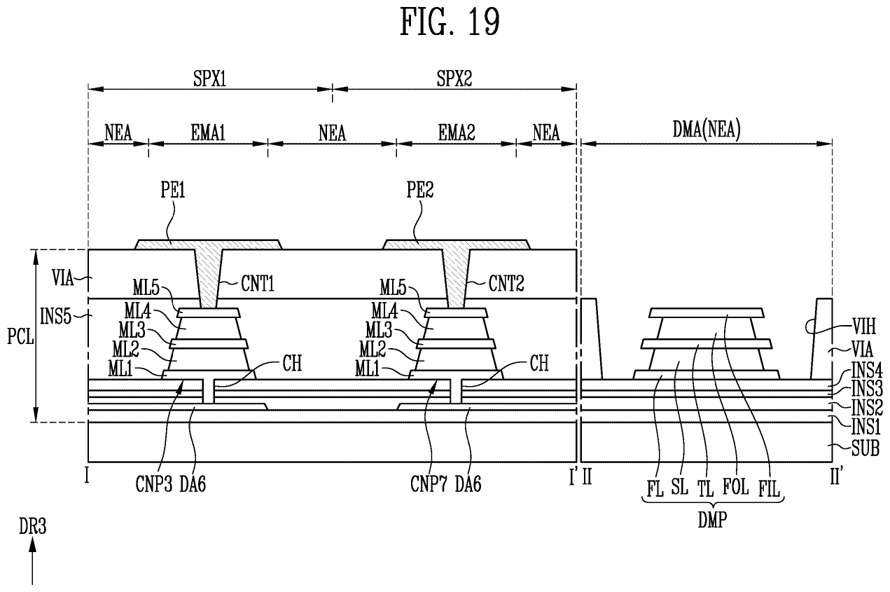

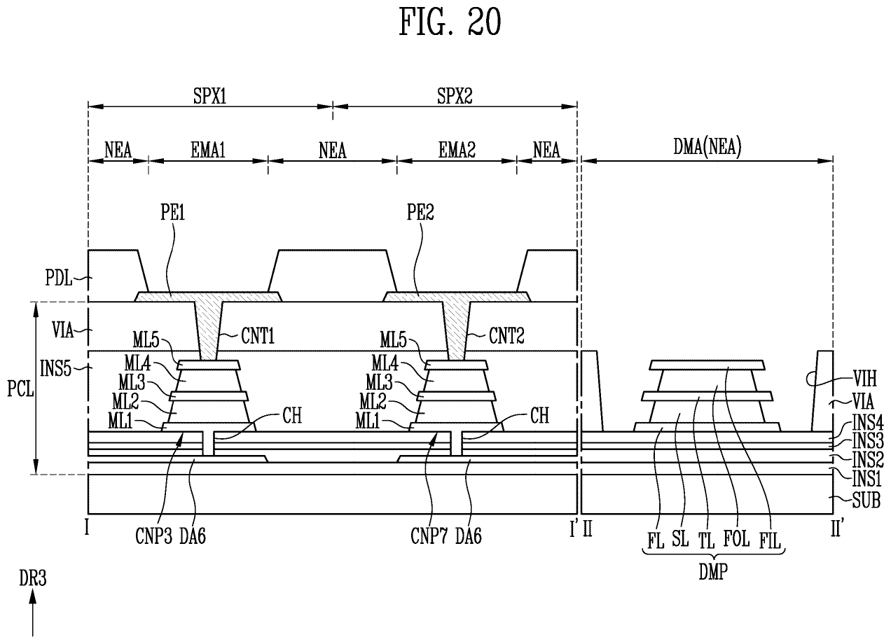

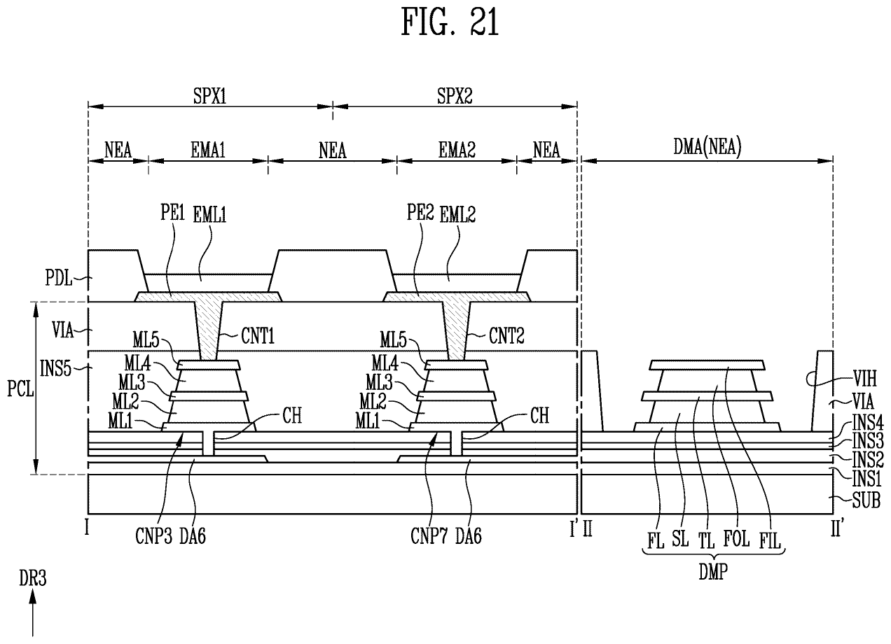

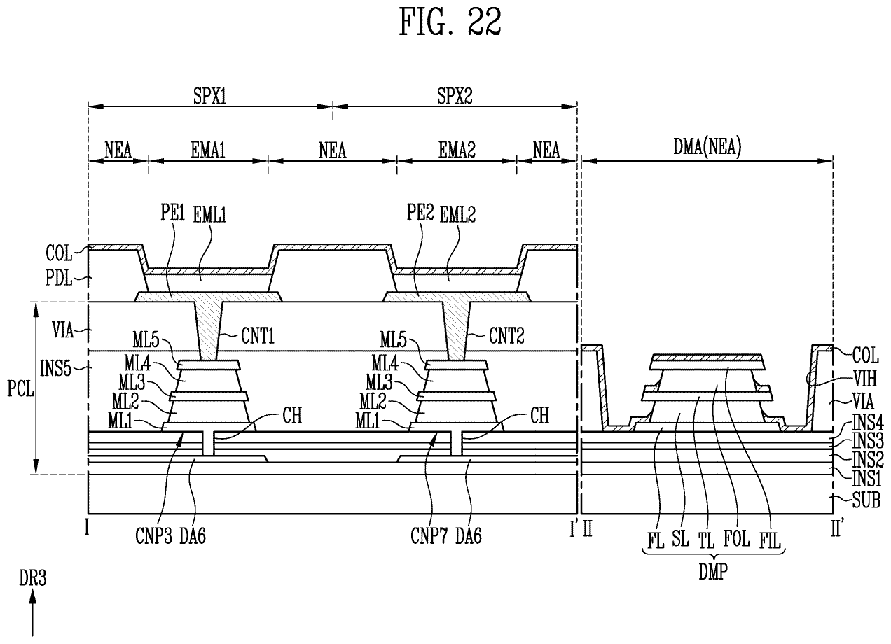

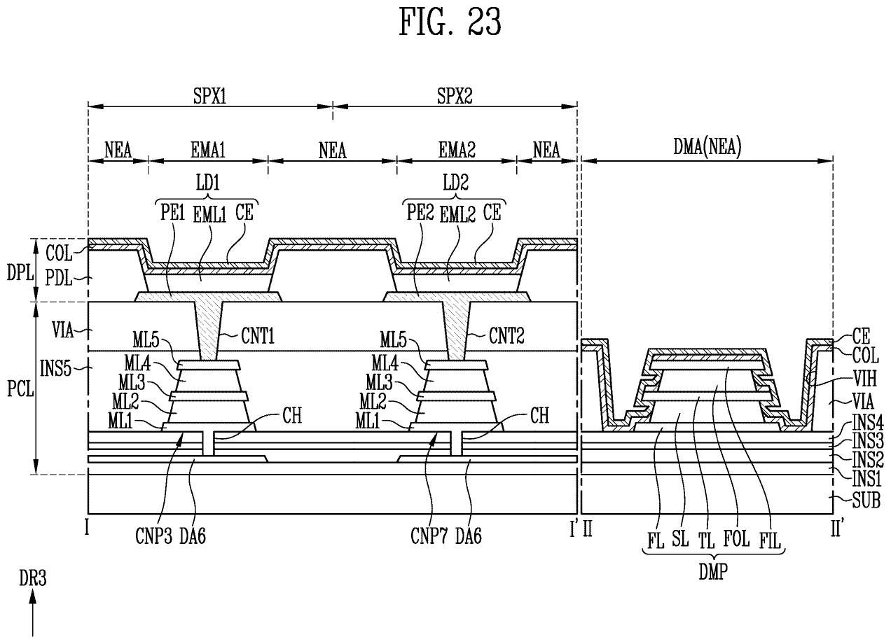

Hereinafter, a manufacturing method of a display device according to an embodiment will be described with reference to FIG. 14 to FIG. 23.

FIG. 14 to FIG. 23 illustrate schematic cross-sectional views of a method of forming the first and second sub-pixels SPX1 and SPX2 of FIG. 9 and the dummy pattern DMP of FIG. 10.

In the embodiment of FIG. 14 to FIG. 23, although manufacturing steps of the display device are described as being performed sequentially according to the cross-sectional views, it is obvious that some steps shown as being continuously performed are simultaneously performed, the order of respective steps is changed, some steps are omitted, or another step is added between respective steps unless the technical scope of the disclosure is changed.

In FIG. 14 to FIG. 23, differences from the above-described embodiment will be mainly described in order to avoid duplicate descriptions.

Referring to FIG. 1 to FIG. 10 and FIG. 14, a first base conductive layer BSL1, a second base conductive layer BSL2, a third base conductive layer BSL3, a fourth base conductive layer BSL4, and a fifth base conductive layer BSL5 are formed on the substrate SUB (or the fourth insulating layer INS4) of the display area DA.

The first base conductive layer BSL1 corresponds to the base material of the first metal layer ML1 and the first layer FL, and may include a conductive material. For example, the first base conductive layer BSL1 may include titanium.

The first base conductive layer BSL1 is formed on the fourth insulating layer INS4, and may be connected to the sixth drain area DA6 of the sixth transistor T6 of each of the first and second pixel circuits PXC1 and PXC2 through the contact hole CH formed through the fourth insulating layer INS4, the third insulating layer INS3 and the second insulating layer INS2 disposed therebelow.

The second base conductive layer BSL2 may be formed on the first base conductive layer BSL1. The second base conductive layer BSL2 corresponds to the base material of the second metal layer ML2 and the second layer SL, and may include a conductive material. For example, the second base conductive layer BSL2 may include aluminum.

The third base conductive layer BSL3 may be formed on the second base conductive layer BSL2. The third base conductive layer BSL3 corresponds to the base material of the third metal layer ML3 and the third layer TL, and may include a conductive material. For example, the third base conductive layer BSL3 may include titanium.

The fourth base conductive layer BSL4 may be formed on the third base conductive layer BSL3. The fourth base conductive layer BSL4 corresponds to the base material of the fourth metal layer ML4 and the fourth layer FOL, and may include a conductive material. For example, the fourth base conductive layer BSL4 may include aluminum.

The fifth base conductive layer BSL5 may be formed on the fourth base conductive layer BSL4. The fifth base conductive layer BSL5 corresponds to the base material of the fifth metal film ML5 and the fifth layer FIL, and may include a conductive material. For example, the fifth base conductive layer BSL5 may include titanium.

The first, second, third, fourth, and fifth base conductive layers BSL1, BSL2, BSL3, BSL4, and BSL5 may be sequentially formed in the same chamber without vacuum breaking.

Referring to FIG. 1 to FIG. 10, FIG. 14, and FIG. 15, the third connection pattern CNP3, the seventh connection pattern CNP7, and the dummy pattern DMP are formed by performing a photolithography process using a mask to collectively pattern the first, second, third, fourth, and fifth base conductive layers BSL1, BSL2, BSL3, BSL4, and BSL5.

Each of the third and seventh connection patterns CNP3 and CNP7 may include the first metal layer ML1, the second metal layer ML2, the third metal layer ML3, the fourth metal layer ML4, and the fifth metal layer ML5 sequentially stacked in the third direction DR3. The third connection pattern CNP3 may be disposed in an area in which the first pixel circuit PXC1 of the first sub-pixel SPX1 is disposed, and the seventh connection pattern CNP7 may be disposed in an area in which the second pixel circuit PXC2 of the second sub-pixel SPX2 is disposed.

The dummy pattern DMP may include the first layer FL, the second layer SL, the third layer TL, the fourth layer FOL, and the fifth layer FIL sequentially stacked in the third direction DR3. The dummy pattern DMP may be disposed in the dummy area DMA.

The first metal layer ML1 and the first layer FL may be formed by the same process, include the same material, and be provided on the same layer. The second metal layer ML2 and the second layer SL may be formed by the same process, include the same material, and be provided on the same layer. The third metal layer ML3 and the third layer TL may be formed by the same process, include the same material, and be provided on the same layer. The fourth metal layer ML4 and the fourth layer FOL may be formed by the same process, include the same material, and be provided on the same layer. The fifth metal layer ML5 and the fifth layer FIL may be formed by the same process, include the same material, and be provided on the same layer.

Referring to FIG. 1 to FIG. 10 and FIG. 14 to FIG. 16, a wet etching process may be performed to selectively etch the second metal layer ML2, the second layer SL, the fourth metal layer ML4, and the fourth layer FOL.

Due to the wet etching process described above, the side surface of the second metal layer ML2 may be recessed from the side surface of each of the first and third metal layers ML1 and ML3, and the side surface of the second layer SL may be recessed from the inside of each of the first and third layers FL and TL. Accordingly, the second metal layer ML2 may have an undercut portion under the third metal layer ML3, and the second layer SL may have an undercut portion under the third layer TL.

For example, due to the above-described etching process, the side surface of the fourth metal layer ML4 may be recessed from the side surface of each of the third and fifth metal layers ML3 and ML5, and the side surface of the fourth layer FOL may be recessed from the side surfaces of each of the third and fifth layers TL and FIL. Accordingly, the fourth metal layer ML4 may have an undercut portion under the fifth metal layer ML5, and the fourth layer FOL may have an undercut portion under the fifth layer FIL.

In the above-described embodiment, it has been described that selective etching of the second metal layer ML2 and the fourth metal layer ML4 is performed together with the second layer SL and the fourth layer FOL, but is not limited thereto. In some embodiments, the second metal layer ML2 and the fourth metal layer ML4 may not be etched (or some thereof may not be removed) because they are covered by a separate mask (for example, an etching mask), and only the second and fourth layers SL and FOL may be etched.

Referring to FIG. 1 to FIG. 10 and FIG. 14 to FIG. 17, the fifth insulating layer INS5 is formed on third and seventh connection patterns CNP3 and CNP7. The fifth insulating layer INS5 may be partially removed in the dummy area DMA to expose the dummy pattern DMP without being formed on the dummy pattern DMP. In other words, the fifth insulating layer INS5 may not be formed on the dummy pattern DMP.

The fifth insulating layer INS5 may be partially removed on the third and seventh connection patterns CNP3 and CNP7 to partially expose each of the third and seventh connection patterns CNP3 and CNP7.

Referring to FIG. 1 to FIG. 10 and FIG. 14 to FIG. 18, the via layer VIA is formed on the fifth insulating layer INS5.

The via layer VIA may include the first contact portion CNT1 exposing a portion of the third connection pattern CNP3 and the second contact portion CNT2 exposing a portion of the seventh connection pattern CNP7.

The via layer VIA may include the via hole VIH exposing the dummy pattern DMP in the dummy area DMA. In the dummy area DMA, the via layer VIA may be formed on the fourth insulating layer INS4, but is not limited thereto. For example, in case that the fifth insulating layer INS5 is disposed in the dummy area DMA in the form including an opening that completely exposes the dummy pattern DMP, the via layer VIA may be formed on the fifth insulating layer INS5.

Referring to FIG. 1 to FIG. 10 and FIG. 14 to FIG. 19, the first pixel electrode PE1 and the second pixel electrode PE2 are formed on the via layer VIA. The first pixel electrode PE1 may be electrically connected to the third connection pattern CNP3 through the first contact portion CNT1, and the second pixel electrode PE2 may be electrically connected to the seventh connection pattern CNP7 through the second contact portion CNT2.

In some embodiments, as described in FIG. 12, the conductive pattern CP may be formed on the dummy pattern DMP. In this case, the conductive pattern CP may be formed by the same process as the first and second pixel electrodes PE1 and PE2, and may include the same material.

Referring to FIG. 1 to FIG. 10 and FIG. 14 to FIG. 20, the pixel defining film PDL is formed on first and second pixel electrodes PE1 and PE2. The pixel defining film PDL may include an opening exposing a portion of each of the first and second pixel electrodes PE1 and PE2.

The pixel defining film PDL may be partially removed in the dummy area DMA to expose the dummy pattern DMP without being formed on the dummy pattern DMP. In other words, the pixel defining film PDL may not be formed on the dummy pattern DMP.

Referring to FIG. 1 to FIG. 10 and FIG. 14 to FIG. 21, the first light emitting layer EML1 is formed on the first pixel electrode PE1 exposed by the opening of the pixel defining film PDL, and the second light emitting layer EML2 is formed on the second pixel electrode PE2 exposed by another opening of the pixel defining film PDL.

Referring to FIG. 1 to FIG. 10 and FIG. 14 to FIG. 22, the control layer COL is formed on the first light emitting layer EML1, the second light emitting layer EML2, and the dummy pattern DMP.

The control layer COL may be commonly provided in the first and second sub-pixels SPX1 and SPX2. For example, the control layer COL may be disposed in the dummy area DMA, and may be formed on the dummy pattern DMP. In this case, the control layer COL in the dummy area DMA may have a disconnection portion on the dummy pattern DMP. The control layer COL may be formed on an upper surface of the fifth layer FIL, a lower end portion of a side surface of the fourth layer FOL, an upper surface of the third layer TL, a lower end portion of a side surface of the second layer SL, and the first layer FL, and may not be formed on an upper end portion of a side surface of the fourth layer FOL covered by the fifth layer FIL and an upper end portion of a side surface of the second layer SL covered by the third layer TL.

Referring to FIG. 1 to FIG. 10 and FIG. 14 to FIG. 23, the common electrode CE is formed on the control layer COL.

The common electrode CE may be commonly provided to first and second sub-pixels SPX1 and SPX2. The common electrode CE may be disposed in the dummy area DMA, and may be formed on the control layer COL and the dummy pattern DMP exposed by the disconnection portion of the control layer COL. In this case, a contact area between the dummy pattern DMP and the common electrode CE may increase to improve contact resistance of the common electrode CE.

The encapsulation layer TFE may be formed on the common electrode CE.

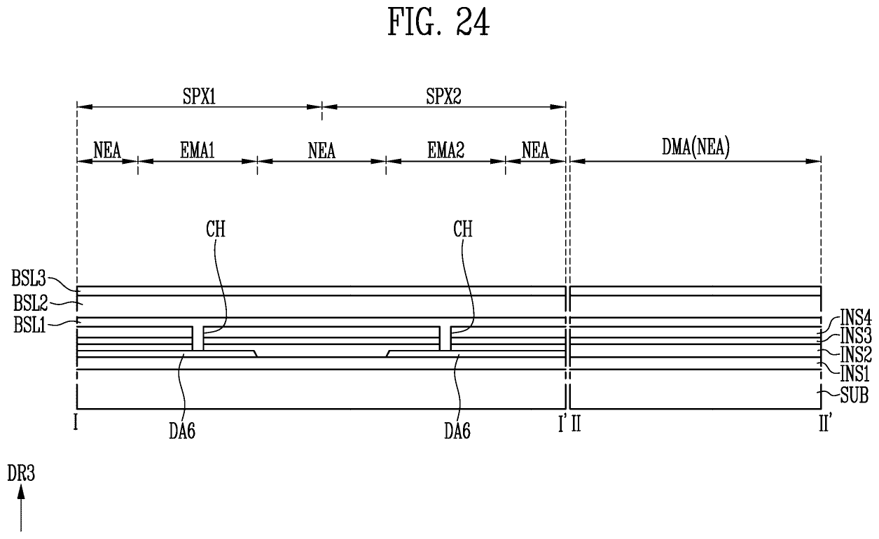

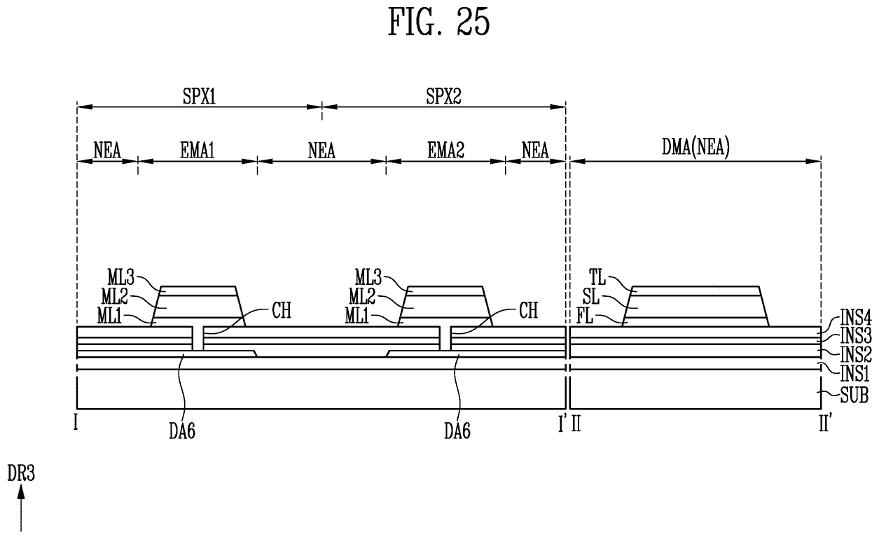

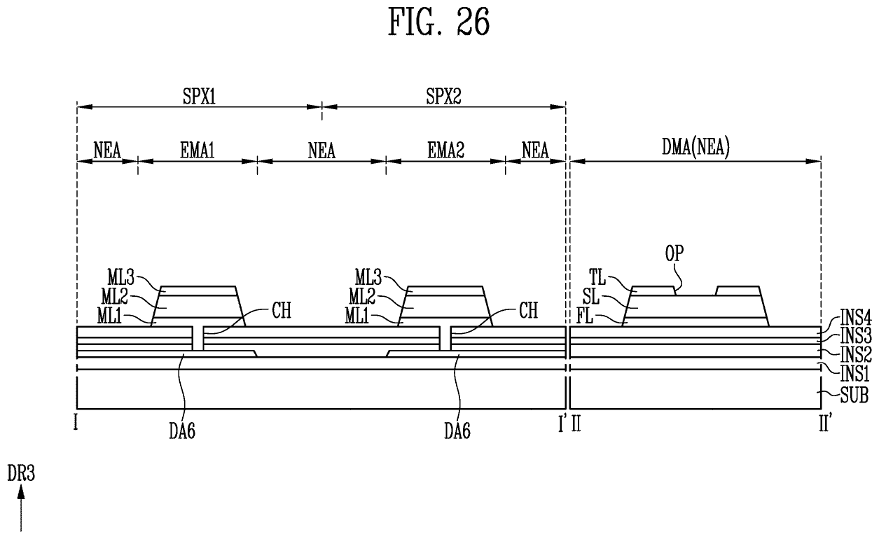

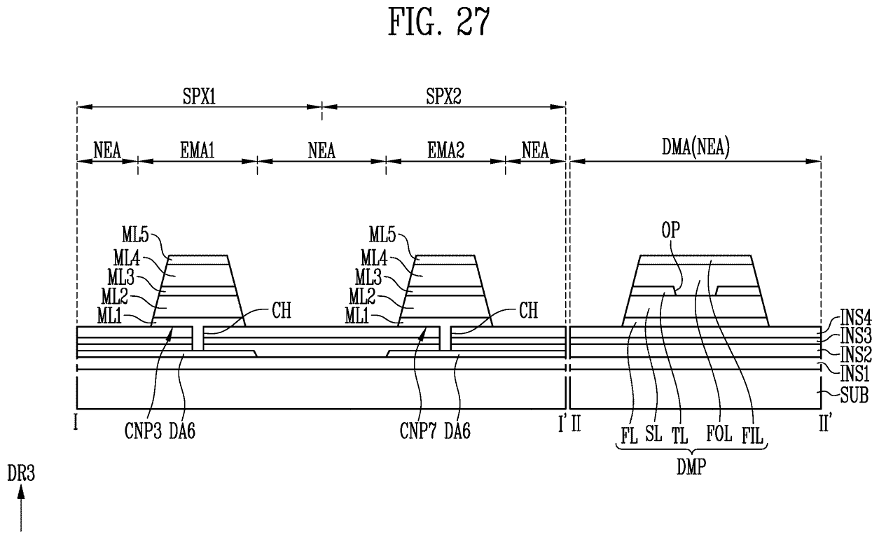

FIG. 24 to FIG. 27 illustrate cross-sectional views of a manufacturing method of forming the third and seventh connected patterns CNP3 and CNP7 of FIG. 9 and the dummy pattern DMP of FIG. 11. Particularly, FIG. 24 to FIG. 27 illustrate a manufacturing method of forming the dummy pattern DMP of FIG. 11.

In FIG. 24 to FIG. 27, differences from the above-described embodiment will be mainly described in order to avoid duplicate descriptions.

Referring to FIG. 1 to FIG. 9, FIG. 11, and FIG. 24, the first base conductive layer BSL1, the second base conductive layer BSL2, and the third base conductive layer BSL3 are formed on the substrate SUB (or the fourth insulating layer INS4) of the display area DA.

The first base conductive layer BSL1 may be formed on the fourth insulating layer INS4, the second base conductive layer BSL2 may be formed on the first base conductive layer BSL1, and the third base conductive layer BSL3 may be formed on the second base conductive layer BSL2. The first base conductive layer BSL1 corresponds to the base material of the first metal layer ML1 and the first layer FL, and may include titanium. The second base conductive layer BSL2 corresponds to the base material of the second metal layer ML2 and the second layer SL, and may include aluminum. The third base conductive layer BSL3 corresponds to the base material of the third metal layer ML3 and the third layer TL, and may include titanium.

The first, second, and third base conductive layers BSL1, BSL2, and BSL3 may be sequentially formed in the same chamber without vacuum breaking.

Referring to FIG. 1 to FIG. 9, FIG. 11, and FIG. 25, the first metal layer ML1 and the first layer FL, the second metal layer ML2 and the second layer SL, and the third metal layer ML3 and the third layer TL are formed by performing a photolithography process using a first mask to collectively pattern the first, second, and third base conductive layers BSL1, BSL2, and BSL3.

Referring to FIG. 1 to FIG. 9, FIG. 11, and FIG. 26, a photolithography process using a second mask is performed to remove a portion of the third layer TL, thereby forming the opening OP exposing a portion of the second layer SL disposed under the third layer TL. When forming the opening exposing a portion of the second layer SL disposed under the third layer TL, an opening exposing a portion of each of the second metal layer ML2 disposed under the third metal layer ML2 in the first sub-pixel SPX1 and the second sub-pixel SPX2 may be simultaneously formed.

Referring to FIG. 1 to FIG. 9, FIG. 11, and FIG. 27, after sequentially forming the fourth base conductive layer (refer to “BSL4” in FIG. 14) and the fifth base conductive layer (refer to “BSL5” in FIG. 14) on the third metal layer ML3 and the third layer TL, a photolithography process using a third mask is performed to form the dummy pattern DMP including the third and seventh connection patterns CNP3 and CNP7 and the first, second, third, fourth, and fifth layers FL, SL, TL, FOL, and FIL respectively including the first, second, third, fourth, and fifth metal layers ML1, ML2, ML3, ML4, and ML5.

The fourth metal layer ML4 may be formed on the third metal layer ML3, and the fifth metal layer ML5 may be formed on the fourth metal layer ML4. The fourth layer FOL may be formed on the third layer TL including the opening OP, and the fifth layer FIL may be formed on the fourth layer FOL.

The fourth layer FOL may directly contact and be connected to the second layer SL by the opening OP of the third layer TL. In this case, the contact characteristic between the common electrode CE and the dummy pattern DMP formed in a subsequent process is improved, so that the contact resistance of the common electrode CE may be further improved.

After forming the third connection pattern CNP3, the seventh connection pattern CNP7, and the dummy pattern DMP, the manufacturing method described with reference to FIG. 16 to FIG. 23 may be sequentially performed.

While the present inventive concept has been shown and described with reference to certain embodiments thereof, it will be understood by those skilled in the art that various changes in forms and details may be made therein without departing from the spirit and scope of the present inventive concept as defined by the appended claims and their equivalents.

Therefore, the technical scope of the present disclosure may be determined by only the technical scope of the accompanying claims.

What is claimed is:

1. A display device comprising:
a connection pattern and a dummy pattern disposed to be spaced apart from each other on a substrate;
a via layer disposed on the substrate and including a contact portion exposing the connection pattern and a via hole exposing the dummy pattern;
a pixel electrode disposed on the via layer and electrically connected to the connection pattern through the contact portion;
a light emitting layer disposed on the pixel electrode;
a control layer disposed on the light emitting layer; and
a common electrode disposed on the control layer,
wherein the dummy pattern includes a first conductive layer, a second conductive layer, a third conductive layer, a fourth conductive layer, and a fifth conductive layer sequentially disposed on the substrate; and
wherein the first conductive layer, the third conductive layer, and the fifth conductive layer include a first conductive material and the second conductive layer and the fourth conductive layer include a second conductive material.

2. The display device of claim 1, wherein the first conductive material includes titanium and the second conductive layer and the fourth conductive layer include aluminum.

3. The display device of claim 2, wherein the second conductive layer and the fourth conductive layer have a thickness greater than that of the first conductive layer, the third conductive layer, and the fifth conductive layer.

4. The display device of claim 2, wherein the first conductive layer, the second conductive layer, the third conductive layer, the fourth conductive layer, and the fifth conductive layer have different thicknesses.

5. The display device of claim 4, wherein a side surface of the second conductive layer is recessed from a side surface of the third conductive layer and a side surface of the fourth conductive layer is recessed from a side surface of the fifth conductive layer.

6. The display device of claim 5, wherein the side surface of the second conductive layer is recessed from a side surface of the first conductive layer and the side surface of the fourth conductive layer is recessed from the side surface of the third conductive layer.

7. The display device of claim 4, wherein the connection pattern includes a first metal layer, a second metal layer, a third metal layer, a fourth metal layer, and a fifth metal layer sequentially disposed on the substrate;
wherein the first metal layer includes the same material as and is disposed on the same layer as the first conductive layer;
wherein the second metal layer includes the same material as and is disposed on the same layer as the second conductive layer;
wherein the third metal layer includes the same material as and is disposed on the same layer as the third conductive layer;
wherein the fourth metal layer includes the same material as and is disposed on the same layer as the fourth conductive layer; and
wherein the fifth metal layer includes the same material as and is disposed on the same layer as the fifth conductive layer.

8. The display device of claim 1, wherein the control layer is disconnected on the dummy pattern disposed in the via hole.

9. The display device of claim 8, wherein the control layer is disposed on an upper surface of the fifth conductive layer, a portion of a side surface of the fourth conductive layer, a portion of an upper surface of the third conductive layer, a portion of a side surface of the second conductive layer, and an upper surface of the first conductive layer; and
wherein the common electrode is disposed on the control layer, side and lower surfaces of the fifth conductive layer, a side surface of the fourth conductive layer, side and lower surfaces of the third conductive layer, and a side surface of the second conductive layer.

10. The display device of claim 8, wherein the third conductive layer includes an opening exposing a portion of the second conductive layer; and
wherein the fourth conductive layer is in direct contact with the second conductive layer via the opening.

11. The display device of claim 8, further comprising a conductive pattern disposed between the dummy pattern and the control layer,
wherein the conductive pattern includes the same material as the pixel electrode.

12. The display device of claim 1, further comprising a transistor disposed between the substrate and the connection pattern and electrically connected to the pixel electrode through the connection pattern.

13. The display device of claim 12, further comprising a data line electrically connected to a transistor and receiving a data signal and a dummy wire disposed to be spaced apart from the data line and integrally formed with the dummy pattern.

14. The display device of claim 1, wherein
the dummy pattern is electrically connected to the common electrode to receive a low potential voltage.

15. A display device comprising:
a sub-pixel disposed on a substrate and including a light emitting element, the light emitting element including a pixel electrode, a light emitting layer disposed on the pixel electrode, a control layer disposed on the light emitting layer, and a common electrode disposed on the control layer;
a connection pattern disposed between the substrate and the light emitting element and electrically connected to the light emitting element;
a data line electrically connected to the sub-pixel and receiving a data signal;
a dummy wire disposed to be spaced apart from the data line; and
a dummy pattern integrally formed with the dummy wire and disposed to be spaced apart from the connection pattern,
wherein the dummy pattern includes a first conductive layer, a second conductive layer, a third conductive layer, a fourth conductive layer, and a fifth conductive sequentially disposed on the substrate; and
wherein the second conductive layer is in direct contact with the fourth conductive layer.

16. The display device of claim 15, wherein the first conductive layer, the third conductive layer, and the fifth conductive layer include titanium, and the second conductive layer and the fourth conductive layer include aluminum; and
wherein the second conductive layer and the fourth conductive layer have a thickness greater than that of the first conductive layer, the third conductive layer, and the fifth conductive layer.

17. The display device of claim 16, wherein a side surface of the second conductive layer is recessed from a side surface of the third conductive layer; and
wherein a side surface of the fourth conductive layer is recessed from a side surface of the fifth conductive layer.

18. The display device of claim 16, wherein the third conductive layer includes an opening exposing a portion of the second conductive layer; and
wherein the second conductive layer and the fourth conductive layer are connected through the opening.

19. A manufacturing method of a display device, comprising:
forming a connection pattern and a dummy pattern disposed to be spaced apart from each other on a substrate;
forming a via layer disposed on the substrate and including a contact portion exposing the connection pattern and a via hole exposing the dummy pattern;
forming a pixel electrode disposed on the via layer and electrically connected to the connection pattern through the contact portion;
forming a light emitting layer disposed on the pixel electrode;
forming a control layer disposed on the light emitting layer; and
forming a common electrode disposed on the control layer,
wherein the dummy pattern includes a first conductive layer, a second conductive layer, a third conductive layer, a fourth conductive layer, and a fifth conductive layer sequentially disposed on the substrate;
wherein the first conductive layer, the third conductive layer, and the fifth conductive layer include titanium, and the second conductive layer and the fourth conductive layer include aluminum; and
wherein a side surface of the second conductive layer is recessed from a side surface of the third conductive layer, and a side surface of the fourth conductive layer is recessed from a side surface of the fifth conductive layer.

20. The manufacturing method of the display device of claim 19, wherein the forming of the dummy pattern includes:
sequentially forming a first base conductive layer, a second base conductive layer, and a third base conductive layer on the substrate;
forming the first conductive layer, the second conductive layer, and the third conductive layer by collectively etching the first base conductive layer, the second base conductive layer and the third base conductive layer;
forming an opening exposing a portion of the second conductive layer by removing a portion of the third conductive layer; and
forming the fourth conductive layer on the third conductive layer and forming the fifth conductive layer on the fourth conductive layer.
